(19) United States
(12) Patent Application Publication
(10) Pub. No.: US 2025/0343021 A1
(43) Pub. Date: Nov. 6, 2025

(54) FAST CLOSED-LOOP CONTROL OF MULTI-BEAM CHARGED PARTICLE SYSTEM

(71) Applicant: Carl Zeiss MultiSEM GmbH, Oberkochen (DE)

(72) Inventors: Markus KOCH, Neu-Ulm (DE); Bjoern MIKSCH, Heidenheim (DE); Dirk ZEIDLER, Oberkochen (DE); Thomas SCHMID, Aalen (DE); Felix MENKE, Oberkochen (DE); Thomas DIETERLE, Murrhardt (DE)

(21) Appl. No.: 19/269,092

(22) Filed: Jul. 15, 2025

Related U.S. Application Data
(63) Continuation of application No. PCT/EP2024/051248, filed on Jan. 19, 2024.

(30) Foreign Application Priority Data
Jan. 19, 2023 (DE) 10 2023 101 358.0

(51) Int. Cl. H01J 37/04; H01J 37/22; H01J 37/244; H01J 37/28

(52) U.S. Cl. CPC H01J 37/04; H01J 37/222; H01J 37/244; H01J 37/28; H01J 2237/20214; H01J 2237/20221; H01J 2237/30488

(57) ABSTRACT

Various examples generally pertain to closed-loop control of one or more parameters of a multi-beam charged particle imaging system, e.g., a multi beam scanning electron microscope, mSEM. A pattern of secondary beamlets can be stabilized. A focal position can be stabilized. According to examples, fast algorithms are facilitated by a field-programmable gated array, FPGA, logic.

### CROSS-REFERENCE TO RELATED APPLICATIONS

The present application is a continuation of, and claims benefit under 35 USC 120 to, international application No. PCT/EP2024/051248, filed Jan. 19, 2024, which claims benefit under 35 USC 119 of German Application No. 10 2023 101 358.0, filed Jan. 19, 2023. The entire disclosure of each of these applications is incorporated by reference herein.

### FIELD

Various examples of the disclosure pertain to techniques of operating a multi-beam charged particle system. For example, various examples relate to a closed-loop control of the multi-beam charged particle system.

### BACKGROUND

With the continuous development of ever smaller and ever more complex microstructures such as semiconductor components, there is a desire to develop and optimize planar production techniques and inspection systems for producing and inspecting small dimensions of the microstructures. The development and production of the semiconductor components often involves high resolution metrology tools with high throughput. The planar production techniques typically involve process monitoring and process optimization for a reliable production with a high throughput. Moreover, there have been recent demands for an analysis of semiconductor wafers for reverse engineering and for a customer-specific, individual configuration of semiconductor components.

Therefore, there is a desire for an inspection mechanism which can be used with a high throughput for examining the microstructures on wafers with great accuracy.

Recently, multi-beam scanning electron microscopes have been introduced to support development and manufacturing of micro-electronic semiconductor components. A multi-beam scanning electron microscope (MSEM) is disclosed in U.S. Pat. No. 7,244,949 B2 and in US 2019/0355544 A1.

In the case of the MSEM, the following generally holds. A sample is irradiated simultaneously with a plurality of individual electron beams forming primary beamlets.

The plurality of J individual primary beamlets are focused on a surface of a sample to be examined by way of an objective lens system. The primary beamlets are arranged in a pattern. By way of example, J=4 to J=10,000 individual electron beams can be provided as primary radiation, with each individual electron beam being separated from an adjacent individual electron beam by a pitch of 1 to 200 micrometers. A typical

MSEM has approximately J=100 separated individual electron beams (“beamlets”), which for example are arranged in a hexagonal pattern, with the individual electron beams being separated by a pitch of approximately 10 μm.

During the illumination of the sample—e.g., a wafer surface—with the primary beamlets, interaction products, for example secondary electrons or backscattered electrons, emanate from the surface of the wafer. Their start points typically correspond to those locations on the sample on which the plurality of J primary beamlets are focused. The amount and the energy of the interaction products generally depend on the material composition and the topography of the wafer surface. The interaction products usually form a plurality of secondary particle beams (secondary beamlets), which are collected by the objective lens system and which are directed by a secondary electron optical imaging system at a detector arranged in an image plane. The secondary beamlets can be focused by the secondary electron optical imaging system and focus points of the secondary beamlets are formed on an image plane, in which the detector is arranged.

The pattern of the secondary beamlets (i.e., the lateral arrangement of the secondary beamlets with respect to each other) can be subject to changes or drifts arising from charging effects of the sample. Charging effects can have a significant influence on secondary electrons generated in interaction volumes close to the surface of a sample. Therefore, the signal strength of collected secondary electrons can be reduced or cross talk can be increased. Cross talk is generally the effect of detection of unwanted secondary electrons by detector pixels, wherein unwanted secondary electrons can result from overlapping secondary beamlets at the detector plane due to a change in the inter-beamlet pitch. This is also referred to as inter-beamlet crosstalk.

S. Rahangdale, P. Keijzer, and P. Kruit, “MBSEM image acquisition and image processing in LabView FPGA.” 2016 International Conference on Systems, Signals and Image Processing (IWSSIP). IEEE, 2016, discloses the use of field programmable gated arrays (FPGAs) for parallel image acquisition and processing in multi-beam scanning electron microscopy.

R. Saini, Y. V. Chaudhari, and S. Pal, “Design of FPGA based scan generator and Image Grabbing System for Scanning Electron Microscope.” 2015 National Conference on Recent Advances in Electronics & Computer Engineering (RAECE). IEEE, 2015, discloses an FPGA-based scan generator and image grabber system for acquiring images in a scanning electron microscope.

C. Diederichs, S. Zimmermann, and S. Fatikow, “FPGA-based object detection and classification inside scanning electron microscopes.” 2012 International Conference on Manipulation, Manufacturing and Measurement on the Nanoscale (3M-NANO). IEEE, 2012, discloses an FPGA for online object detection and classification by connected component labeling in SEM images.

### SUMMARY

There is a desire for advanced techniques of operating multi-beam charged particle devices such as MSEMs. A desire exists for techniques that keep the imaging conditions stable such that the imaging can be carried out with enhanced reliability, enhanced throughput, and enhanced repeatability. A desire exists for reducing inter-beam crosstalk and drifts of the pattern of the secondary beamlets.

The techniques disclosed herein can help to reduce charging effects during the inspection of semiconductor samples. The techniques can help to keep imaging conditions stable even for multi-beam charged particle devices that comprise a large number of secondary beamlets, e.g., more than 100 or more than 500 beamlets. The techniques can help to keep imaging conditions stable even for multi-beam charged particle devices that provide a fast raster speed of, e.g., more than 20 Hz or even more than 50 Hz. The techniques can help to reduce inter-beamlet crosstalk.

In an aspect, the disclosure provides a computer-implemented method of operating a multi-beam charged particle imaging device which includes implementing a closed-loop control process while raster-scanning a pattern of multiple charged particle beams across a sample. This closed-loop control process includes stabilizing one or more parameters of the secondary beamlets towards a setpoint. This stabilizing is based on a multi-pixel image of the secondary beamlets.

The disclosure provides a computer program which includes program code that can be loaded by a control circuitry and executed by the control circuitry. The control circuitry, upon executing the program code, perform such method.

The disclosure provides a multi-beam charged particle imaging device which is configured to execute such method.

In an aspect, the disclosure provides a computer-implemented method of operating a multi-beam charged particle imaging device. The method includes, while raster-scanning a pattern of multiple charged particle beams across a sample, implementing a closed-loop control process. The closed-loop control process includes stabilizing a pattern of secondary beamlets. This stabilization is towards a setpoint. The closed-loop control process also includes capturing a multi-pixel image of the secondary beamlets. The closed-loop control process further includes determining a current estimate of the pattern of secondary beamlets based on the multi-pixel image of the secondary beamlets. According to examples, a section of the closed-loop control process that determines the current estimate of the pattern of the secondary beamlets based on the multi-pixel images implemented at least partly in a field-controlled programmable array (FPGA) logic.

The disclosure provides a computer program or a computer-program product or a computer-readable storage medium which includes program code. The program code can be loaded and executed by at least one control circuitry. The at least one control circuitry, upon loading and executing the program code, perform such method of operating the multi-beam charged particle device.

In an aspect, the disclosure provides a control circuitry for operating a multi-beam charged particle imaging device. The control circuitry is configured to implement a closed-control process while raster-scanning a pattern of multiple charged particle beams across a sample. The closed-loop control process includes stabilizing a pattern of secondary beamlets towards a setpoint. The closed-loop control process includes capturing a multi-pixel image of the secondary beamlets and determining a current estimate of the pattern of the secondary beamlets based on the multi-pixel image of the secondary beamlets. A section of the closed-loop control process that determines the current estimate of the pattern of the secondary beamlets based on the multi-pixel images implemented at least partly in a field-controlled programmable array logic of the control circuitry.

In an aspect, the disclosure provides a computer-implemented method of operating a multi-beam charged particle imaging device which includes determining one or more current closed-loop control parameters in a calibration process. The method also includes loading a sample object into the multi-beam charged particle imaging device and imaging the sample object using the multi-beam charged particle imaging device and contemporaneously applying a closed-loop control of at least one parameter of secondary beamlets. The closed-loop control is based on the one or more closed-loop control parameters determined in the calibration process.

The closed-loop control process for stabilizing the secondary beamlet pattern towards a setpoint can utilize matrix multiplication techniques to allow efficient computation of control signals. The captured multi-pixel image of the secondary beamlets can be processed, for example, using matrix multiplication with a sparse matrix, in order to determine the individual beamlets for providing the current beamlet pattern estimate. The current estimate can be processed using matrix multiplication in a least square fit using a predetermined pseudo-inverse matrix of a transformation matrix of an affine transformation, in order to determine the parameters of the affine transform that aligns the beamlets best to the setpoint pattern.

Stabilizing the secondary beamlet pattern towards a setpoint can comprise determining an affine transformation between the current estimate of the pattern of the secondary beamlets and the setpoint. Determining an affine transformation between the current estimate of the pattern of the secondary beamlets and the setpoint can be performed (optionally only) by matrix multiplication. For example, by executing a least square fit of transformation parameters of the affine transformation using a predetermined pseudoinverse of a transformation matrix determined based on the setpoint.

The affine transform parameters can be processed using matrix multiplications to determine the correction signals to apply to beam adjusting elements. The techniques can provide the control signals to physically correct the beamlet positions using (optionally only) matrix multiplications.

The disclosure provides a computer program includes program code that can be loaded and executed by control circuitry. The control circuitry, upon executing the program code, perform such method.

The disclosure provides a control circuitry of a multi-beam charged particle device configured to execute such method. It is to be understood that the features mentioned above and those yet to be explained below may be used not only in the respective combinations indicated, but also in other combinations or in isolation without departing from the scope of the disclosure.

### BRIEF DESCRIPTION OF THE DRAWINGS

FIG. 1 schematically illustrates a multi-beam charged particle imaging device according to various examples.

FIG. 2 schematically illustrates an aperture plate for primary beamlets used for illuminating a sample in the multi-beam charged particle imaging device according to various examples.

FIG. 3 schematically illustrates a reference pattern of secondary beamlets formed by primary beamlets at the sample according to various examples.

FIG. 4A schematically illustrates a pattern of the secondary beamlets in an imaging plane according to various examples.

FIG. 4B schematically illustrates a stabilized pattern of the secondary beamlets in the imaging plane according to various examples.

FIG. 5 schematically illustrates certain details with respect to a detector system according to various examples, the detector system comprising a primary detector and a secondary detector.

FIG. 6 schematically illustrates an arrangement of detector elements of a primary detector of the detector system according to various examples.

FIG. 7 schematically illustrates a processing device including a field-programmable gated array and a microprocessor according to various examples.

FIG. 8 is a flowchart of a method according to various examples.

FIG. 9A schematically illustrates a closed-loop control process according to various examples.

FIG. 9B schematically illustrates applying control signals to compensate offsets of a parameter value of secondary beamlets towards a setpoint according to various examples.

FIG. 10 is a flowchart of a method according to various examples.

FIG. 11 schematically illustrates intensity pixel values of multiple pixels of a multi-pixel image acquired using a multi-pixel detector and associated pixel clusters according to various examples.

FIG. 12 schematically illustrates a multi-pixel image of secondary beamlets and associated pixel clusters according to various examples.

FIG. 13 illustrates the centers of the secondary beamlets extracted from the image of FIG. 12.

FIG. 14A schematically illustrates a transformation field of a linear affine transformation determined for the pattern of the secondary beamlets according to FIG. 12 and FIG. 13.

FIG. 14B illustrates dependencies of magnification and defocus on charge-up of the sample.

FIG. 15 schematically illustrates formation of difference images based on a reference image and a current image of secondary beamlets according to various examples.

FIG. 16 schematically illustrates a recursive filter according to various examples.

FIG. 17 schematically illustrates parallel closed-loop control and image exposure and transfer according to various examples.

### DETAILED DESCRIPTION

Some examples of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

In the following, embodiments of the disclosure will be described in detail with reference to the accompanying drawings. It is to be understood that the following description of embodiments is not to be taken in a limiting sense. The scope of the disclosure is not intended to be limited by the embodiments described hereinafter or by the drawings, which are taken to be illustrative only.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Hereinafter, techniques of providing a closed-loop control of secondary beamlets is provided. Multiple parameters of the secondary beamlets can be controlled. In a first example, a pattern of the secondary beamlets is controlled. This means that a magnification of the pattern (correlating with a change in the inter-beamlet pitch) is controlled; alternatively or additionally a translation and/or a rotation of the pattern (the magnification, i.e., the change of the inter-beamlet pitch is sometimes also referred to as scale error) are controlled. Also, the magnification/inter-beamlet pitch can vary for orthogonal directions which would lead to a distortion of the pattern of secondary beamlets: Also, this distortion can be controlled. According to examples of the disclosure, a closed-loop control process stabilizes the pattern of secondary beamlets towards a setpoint. Alternatively or additionally, in a second example, a defocus of the secondary beamlets is controlled in some examples of the disclosure. The defocus will result in a change of the size of the secondary beamlets in the imaging plane. By monitoring the size of the secondary beamlets, the defocus can be minimized.

The closed-loop control of the pattern of secondary beamlets in an imaging plane of a multi-beam charged particle is provided contemporaneously to imaging a sample object using the secondary beamlets.

The disclosed techniques can help enable low-latency control. This can be achieved at least partly by pre-determining one or more closed-loop control parameters in a calibration process, prior to commencing imaging of the sample object. Alternatively or additionally, processing of the closed-loop control can be distributed between multiple compute units, e.g., between a Field Programmable Gated Array (FPGA) logic and a microprocessor. This enables high quality imaging of the sample object, because any disturbances to the secondary beamlets can be counteracted via the close-loop control process at low latency.

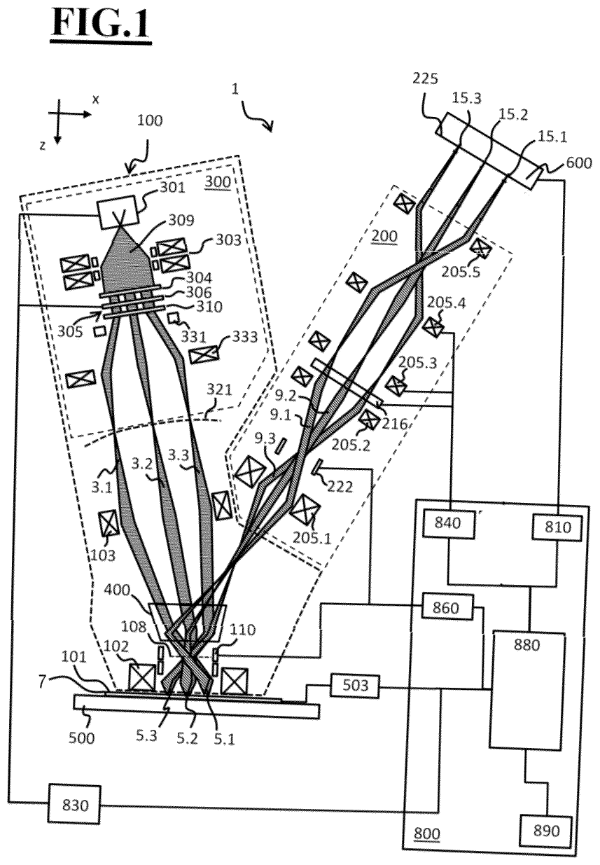

FIG. 1 is a schematic illustration of a multi-beam charged particle imaging device 1 (or simply a multi-beam device 1). Further information relating to such multi-beam devices and components used therein, such as, for instance, particle sources, multi-aperture plate and lenses, can be obtained from the international patent applications WO 2005/024881, WO 2007/028595, WO 2007/028596, WO 2011/124352 and WO 2007/060017 and the German patent applications having the publication numbers DE 10 2013 016 113 A1 and

DE 10 2013 014 976 A1, the disclosure of which in the full scope thereof is incorporated by reference in the present application.

The multi-beam device 1 uses a plurality of charged particle beams for forming an image of an object 7. The multi-beam device 1 generates a plurality of J primary beamlets 3.1, 3.2, 3.3 which strike the sample object 7 in order to generate interaction products, e.g., secondary electrons, which emanate from the object 7 and are subsequently detected.

The multi-beam device 1 is of the MSEM type: the primary beamlets 3.1, 3.2, 3.3 are formed by electrons which are incident on a surface of the object 7 at a plurality of locations and generate a plurality of primary electron beam focus spots 5,1 5.2, 5.3 that are spatially separated from one another.

The object 7 to be examined can be of any desired type, e.g., a semiconductor wafer or a semiconductor mask, and can comprise an arrangement of miniaturized elements.

The surface of the object 7 is arranged in an object plane 101 of an objective lens system 102 of a first particle optical unit 100 (also referred to as illumination system).

A diameter of the minimal beam spots or focus spots 5,1 5.2, 5.3 shaped in the object plane 101 can be small. Exemplary values of this diameter are below four nanometers, for example three nm or less. The focusing of the primary beamlets 3.1, 3.2, 3.3 for shaping the focus spots 5,1 5.2, 5.3 is carried out by the objective lens system 102. In this case, the objective lens system 102 can comprise a magnetic immersion lens. Further examples of focusing mechanisms are described in the German patent DE 102020125534 B3, the entire content of which is herewith incorporated in the disclosure.

The plurality of focus spots 5,1 5.2, 5.3 of the primary beamlets form a pattern in the object plane 101.

The number J of primary beamlets 3.1, 3.2 and 3.3 may be five, twenty-five, or more (for sake of simplicity, only three primary beamlets 3.1, 3.2 and 3.3 with corresponding focus points 5.1, 5.2 and 5.3 are shown in FIG. 1).

In practice, the number of beamlets J, and hence the number of incidence locations or focus spots 5,1 5.2, 5.3, can be chosen to be significantly greater, such as, for example, J=10×10, J=20×30 or J=100×100. Exemplary values of the pitch P2 between the incidence locations are 1 micrometer, 10 micrometers, or more, for example 40 micrometers.

The primary beamlets 3.1, 3.2, 3.3 striking the object 7 generate interaction products, e.g., secondary electrons, back-scattered electrons, which emanate from the surface of the object 7, or primary particles that have experienced a reversal of movement for other reasons. The interaction products emanating from the surface of the object 7 are shaped by the objective lens system 102 to form secondary beamlets 9.1, 9.2, 9.3. Secondary electrons included in the secondary beamlets 9.1, 9.2, 9.3 are used for imaging.

The multi-beam device 1 provides a detection beam path for guiding the plurality of secondary beamlets 9.1, 9.2, 9.3 to a secondary electron imaging system 200. The secondary electron imaging system 200 includes several electron-optical lenses 205.1 to 205.5 for directing the secondary beamlets 9.1, 9.2, 9.3 towards a spatially resolving detector system 600.

The imaging with the secondary electron imaging system 200 is strongly magnifying such that both the pattern of the primary beamlets on the wafer surface and the size and shape of focal points of the primary beamlets are imaged in much magnified fashion. By way of example, a magnification is between 100× and 300× such that one nm on the wafer surface is imaged enlarged to between 100 nm and 300 nm. In an example, an image field of a multi-beam device with for example 100 μm diameter is enlarged to approximately 30 mm.

The primary beamlets 3.1, 3.2, 3.3 are generated in a beam generation apparatus 300 comprising at least one particle source 301 (e.g., an electron source), at least one collimation lens 303, a multi-aperture arrangement 305 and a first field lens 331 and a second field lens 333. The particle source 301 generates at least one diverging particle beam 309, which is at least substantially collimated by the at least one collimation lens 303, and which illuminates the multi-aperture arrangement 305. The multi-aperture arrangement 305 includes an aperture plate 304 (also referred to as filter plate or multi-hole aperture plate), which has a plurality of J openings formed therein in a first raster arrangement. Particles of the illuminating particle beam 309 pass through the J apertures or openings of the first aperture plate 304 and form the plurality J of primary beamlets 3.1, 3.2, 3.3. Particles of the illuminating particle beam 309 which strike the first aperture plate 304 are absorbed by the latter and do not contribute to the formation of the primary beamlets 3.1, 3.2, 3.3. A multi-aperture arrangement 305 usually has at least a further multi-aperture plate 306, for example a lens array, a stigmator array, or an array of deflection elements.

Together with the field lens 331 and a second field lens 333, the multi-aperture arrangement 305 focuses each of the primary beamlets 3.1, 3.2, 3.3 in such a way that focal points are formed in an intermediate image surface 321. Alternatively, the beam foci and the intermediate image surface 321 can be virtual. The intermediate image surface 321 can be curved to pre-compensate a field curvature of the imaging system arranged downstream of the intermediate image surface 321.

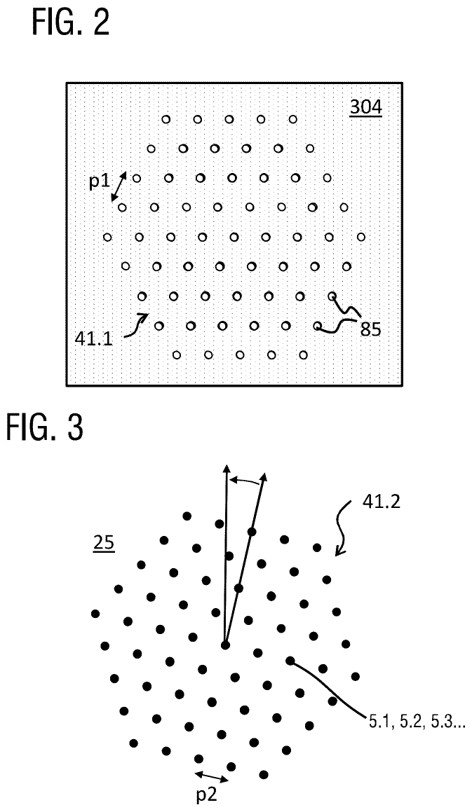

The at least one field lens 103 and the objective lens system 102 provide a first imaging particle optical unit for imaging the surface 321, in which the beam foci are formed, onto the object plane 101 such that a second pattern of focus spots 5,1 5.2, 5.3 of the primary beamlets 3.1, 3.2, 3.3 is formed there. Typically, the surface 25 of the object 7 is arranged in the object plane 101, and the focal spots 5,1 5.2, 5.3 are correspondingly formed on the object surface 25 (see also FIG. 2b). The plurality of primary beamlets 3.1, 3.2, 3.3 form a crossover point 108, in the vicinity of which a first scanning deflector 110 is arranged. The first scanning deflector 110 is used to deflect the plurality of primary beamlets 3.1, 3.2, 3.3 collectively and synchronously such that the plurality of focus spots 5,1 5.2, 5.3 are moved simultaneously over the surface 25 of the object 7. Raster scanning is implemented, thereby imaging the sample object 7. The first scanning deflector 110 is driven by a scanning control unit 860 such that in an inspection mode of operation, a plurality of two-dimensional image data of the surface is acquired. Additionally, the multi-beam device 1 can include further static deflectors configured to adjust the position of the plurality of the primary beamlets 3.1, 3.2, 3.3.

The objective lens system 102 and the projection lenses 205 provide a secondary electron imaging system 200 for imaging the object plane 101 onto an imaging plane 225. The objective lens system 102 is thus a lens or a lens system that is part of both the first and the second particle optical unit, while the field lenses 103, 331 and 333 belong only to the first particle optical unit 100, and the projection lenses 205 belongs only to the secondary electron imaging system 200.

A beam divider 400 is arranged in the beam path of the first particle optical unit 100 between the field lens 103 and the objective lens system 102. The beam divider 400 is also part of the second optical unit in the beam path between the objective lens system 102 and the projection lenses 205.

The first deflection scanner 110 is arranged in a primary electron beam path or in a joint electron beam path. In the example shown in FIG. 1, the secondary beamlets 9.1, 9.2, 9.3 transmit during use the first deflection scanner 110 in opposite direction and the scanning movement of the secondary beamlets 9.1, 9.2, 9.3 is partially compensated. The secondary electrons have typically a different kinetic energy compared to the primary electrons. Therefore, the scanning movement of the moving irradiation positions is only partially compensated. To fully compensate the scanning movement of the secondary beamlets 9.1, 9.2, 9.3, the collective beam deflector 222 is arranged in the secondary electron beam path.

The secondary electron imaging system 200 includes the second, collective beam deflector 222 which is arranged in the vicinity of a crossover point of the secondary beamlets 9.1, 9.2, 9.3. The second, collective beam deflector 222 is operated synchronously with the first deflection scanner 110 and compensates during use a beam deflection of the secondary beamlets 9.1, 9.2, 9.3 such that centers 15 of the beamlets 9 remain at constant position on the imaging plane 225. Thereby, each secondary beamlet 9 is kept within the area of a set of detection elements, which is assigned to the individual secondary beamlet 9.

The secondary electron imaging system 200 includes electron-optical lenses 205.1 to 205.5 to adjust a focus plane of the secondary beamlets 9.1, 9.2, 9.3. A defocus can be applied. The electron-optical lenses 205.1 to 205.5 can thus implement corrective elements for correct the focus plane. The electron-optical lenses 205.1 to 205.5 are shown as magneto-optical elements but are not limited to magneto-optical elements and can comprise also electro-static lens elements or stigmators. With the electron-optical lenses 205.1 to 205.5, the secondary beamlets 9.1, 9.2, 9.3 can be focused into the imaging plane 225 of the secondary electron imaging system 200.

The secondary electron imaging system 200 can include a plurality of further corrective elements, for example at least one of a multi-aperture array element, a deflector or an exchangeable aperture stop. Together with the objective lens system 102, the lenses serve to focus the secondary beamlets 9.1, 9.2, 9.3 on the spatially resolving detector system 600 and, in the process, allow to correct or compensate the magnification and rotation of the pattern of the secondary beamlets 9.1, 9.2, 9.3 in the imaging plane 225. Thereby, the pattern of the plurality of secondary beamlets 9.1, 9.2, 9.3 can stabilized. For example, a first and second magnetic lenses 205.4 and 205.5 (as further examples of corrective elements) are designed in reversed order to one another and have oppositely directed magnetic fields. A Larmor rotation of the secondary beamlets 9.1, 9.2, 9.3 can be compensated by suitably applying control signals to (driving) the magnetic lenses 205.4 and 205.5. The secondary electron imaging system 200—in the illustrated example—includes further corrective elements, specifically a multi-aperture plate 216.

The multi-beam device 1 furthermore includes a control system 800 configured both for controlling the individual particle optical components of the multiple particle beam system and for evaluating and analyzing the signals obtained by the detector system 600. In this case, the control or controller system 800 can be constructed from a plurality of individual electronic computers or electronic components. By way of example, the control system 800 includes a control processor 880, a control module 840 for the control of the electron-optical elements of the secondary electron imaging system 200, and a control module 830 for the control of the electron-optical elements of the primary beamlet generation unit. The control system 800 is further connected to a control module 503 for supplying a voltage to the object 7, the voltage also being referred to as extraction voltage. Thereby, during use, an extraction field is generated between the objective lens system 102 and the surface 25 of the object 7. During use, the extraction field decelerates the primary charged particles of the primary beamlets 3.1, 3.2, 3.3 before the object surface 25 is reached and generates an additional focusing effect on the plurality of primary beamlets 3.1, 3.2, 3.3. At the same time, the extraction field serves during use to accelerate the secondary particles out of the surface 25 of the object 7.

Further, the control system 800 includes the scanning control unit 860 for the raster scanning.

The detector system 600 includes a plurality of sets of detection elements with one set of detection elements for each secondary beamlet 9. During use, each set of detection elements is configured to record the intensity signal of the assigned secondary beamlet 9. The plurality of intensity signals for the plurality of secondary beamlets 9.1, 9.2, 9.3 is transferred to the image data acquisition unit 810, where the image data is processed and stored in memory 890.

Imaging of the sample object can be disturbed by charging of the sample object during imaging. The charging level of the sample object depends on several factors such das the deposited charge by the primary beamlets. The primary particle current of a primary beamlet 3 and the dwell time define the charging level. The product of both defines the deposited charge per pixel which can be accumulated over a large scanning area. Another factor impacting charging level is the backscattered electron yield.

The backscattered electron yield depends on the material composition of the sample. Another factor impacting charging level is the secondary electron yield. The secondary electron yield depends on the material composition of the sample. The secondary electron yield further depends on the kinetic energy of a primary beamlet. The kinetic beam energy of the primary charged particles-as they reach the sample surface-is determined by the extraction field generated by voltage supply unit 503. During irradiation, secondary electrons are generated, which may leave the sample and are extracted by the extraction field. Secondary and backscattered electrons reduce the deposited charge to form a residual charge. Another factor impacting charging level are discharge effects that further reduce the residual charge. Fully conducting samples may not hold charges and the residual charge is instantly be reduced or distributed. Fully isolating samples may locally hold charges for longer time of for example seconds, and deposited charges are only reduced by thermal diffusion or leak currents at for example defects. Semiconductor sample may have spatially varying decay times between instant discharging of conductors connected to large capacities, slow discharging within seconds due to thermal diffusion in semiconductors, and even slower discharging effects in polymers such as photoresist or isolated memory cells. The secondary electron yield is a function of the primary beam energy. The backscattered electron and secondary electron yield and discharge effects depends on the material composition of the sample.

As explained above, the multi-beam device 1 includes a mechanism for generating multiple primary beamlets 3.1, 3.2, 3.3 which are arranged in a first pattern. This first pattern is matched to the apertures of the aperture plate 304. An example of the first pattern 41.1 is illustrated in FIG. 2.

FIG. 2 shows the first aperture plate 304 with apertures 85 forming the first pattern 41.1. In this example, the first pattern 41.1 is a hexagonal raster with a raster pitch p1 of for example 100 μm.

FIG. 3 shows the origins of the secondary beamlets 9.1, 9.2, 9.3, formed by the focus spots 5.1, 5.2, 5.3 (cf. FIG. 1) of the primary beamlets 3.1, 3.2, 3.3. At each irradiation position of a surface 25 of an object 7 with a primary beamlet 3.1, 3.2, 3.3, secondary electrons are generated which form the plurality of secondary beamlets 9.1, 9.2, 9.3. The origins of the plurality of secondary beamlets 9.1, 9.2, 9.3 therefore form a second pattern 41.2 which is defined by the first pattern 41.1 of the primary beamlets 3.1, 3.2, 3.3 (but may nonetheless deviate to some extent). The second pattern 41.2 can be rotated with respect to the first pattern 41.1 and can have a different pitch of for example p2=10 μm (as is apparent from a comparison of FIG. 2 and FIG. 3).

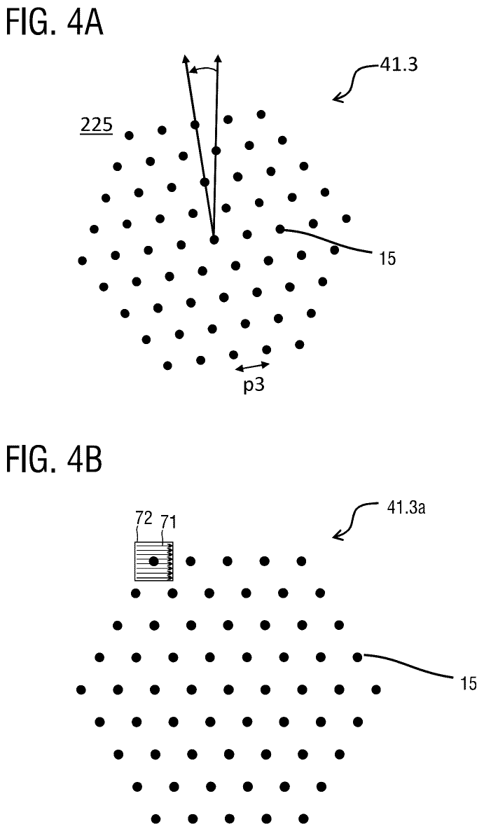

FIG. 4A shows the centers 15 of the secondary beamlets 9.1, 9.2, 9.3 in the imaging plane 225. During use, the centers 15 of the secondary beamlets 9.1, 9.2, 9.3 form a third pattern 41.3. A third pitch of p3=1000 μm is illustrated.

Without stabilization, the third pattern 41.3 can differ with respect to the first and second patterns 41.1 and 41.2. It can be, e.g., distorted, translated, rotated, skewed, and/or magnified. Also, a defocus can be present. This changes the size (i.e., the width) of the secondary beamlets 9.1, 9.2, 9.3 in the imaging plane. Such deviations decrease the image quality or even lead to total loss of signal. Techniques are disclosed that enable to stabilize the pattern 41.3 of the secondary beamlets 9.1, 9.2, 9.3 in the imaging plane 225 towards a setpoint, i.e., a reference pattern. Alternatively or additionally to such stabilization of the pattern 41.3, it is also possible to minimize a defocus of the secondary beamlets 9.1, 9.2, 9.3 in the imaging plane 225. This corresponds, in other words, to stabilizing the focal position of the secondary beamlets 9.1, 9.2, 9.3 towards a set point, typically the imaging plane 225.

FIG. 4B illustrates a stabilized third pattern 41.3a of the secondary beamlets 9.1, 9.2, 9.3 in the imaging plane 225. This corresponds to a setpoint of a respective closed-loop control process.

FIG. 4B also illustrates raster-scan lines 71 for imaging the sample (this is only illustrated for one of the secondary beamlets for simplicity). Each secondary beamlet is scanned within a respective mini field of view (mFOV) 72.

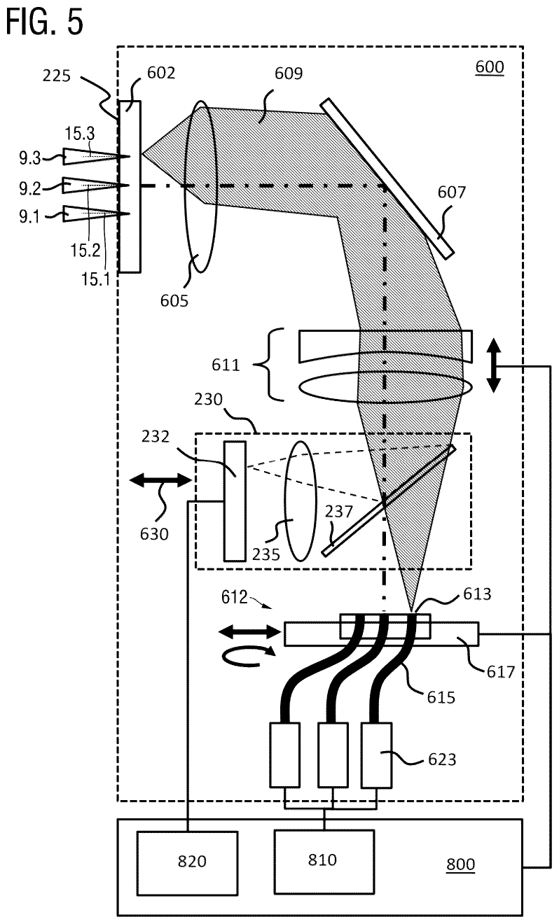

An example of a detector system 600 of the multi-beam device 1 is illustrated in FIG. 5. The detector system 600 includes an electron-to-light conversion element 602, arranged in the imaging plane 225. The electron-to-light conversion element 602 is configured to convert the secondary electrons of the secondary beamlets 9.1, 9.2, 9.3 into light. The detector further includes an optical relay system with optical elements 605 and 611 for imaging and guiding the excited light from the electron-to-light conversion element 602 to detection elements 623. For that purpose, the optical relay system can include a zoom lens system 611, mirrors 607, rotating prisms (not shown) and light guiding fibers 615. In the example of FIG. 5, the detector system 600 is configured to image the excited light from the electron-to-light conversion element 602 into an image plane of a primary detector 612, in which a plurality of entrance openings 613 of optical fibers 615 are arranged. Each entrance opening 613 is associated with a secondary beamlet.

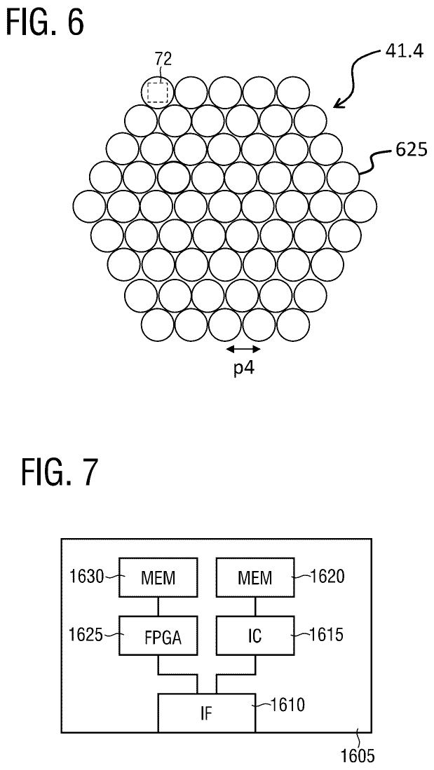

A fourth pattern 41.4 of these entrance openings 613 is shown in FIG. 6. The fourth pattern 41.4 is thereby defined by the arrangement of the entrance openings 613 of the optical fibers 615, and by the magnification by the optical system comprising lens 605 and zoom lens 611. The size of the entrance openings 613 matches the size of the mFOVs 72 (cf. FIG. 4B).

If the third pattern 41.3 changes over time, it is possible that the secondary beamlets drift in-between the entrance openings 613; which can degrade the image quality. This corresponds to inter-beamlet crosstalk.

To counter inter-beamlet crosstalk, the plurality of fiber ends defining the entrance openings 613 are fixed in a movable frame 617, which can be displaced or rotated. With zoom lens 611 or movable frame 617, a position and a rotation of the fourth pattern of entrance openings 613 of fibers 615, corresponding to the sets of detection elements 625, can be adjusted to the third pattern 41.3 of centers 15 formed in the imaging plane 225. Thereby, a maximum signal strength with a minimum cross talk is achieved.

However, it has been found that, in particular, for large counts of secondary beamlets such stabilization via the movable frame 617 is difficult to achieve. The same applies for a large refresh rates. Changes in the magnification or distortions cannot be accounted for. Accordingly, by stabilizing the third pattern 41.3 towards a setpoint and/or minimizing defocus, as disclosed herein, it is possible to mitigate these effects otherwise obtained from drifting secondary beamlets.

To achieve such control of the third pattern 41.3 and/or defocus, the detector system 600 further includes a monitoring system 230 with a multi-pixel detector 232 including multiple pixels 626; the monitoring system 230 also includes an optical relay lens 235 of the monitoring system 230.

The monitoring system 230 is coupled by a beam divider 237. The multi-pixel detector 232 typically operates at a slow frame rate of for example of 0.1 to 1 kHz and is thus not capable to collect the intensity signals at raster-scanning speed of about 20 MHz to 80 MHz. The multi-pixel detector 232 acquires multi-pixel images of the secondary beamlets 9.1, 9.2, 9.3. These are used to stabilize the third pattern 41.3. For example, referring to FIG. 4B, a typical mFOV can include 1000 raster-scan lines 71. The time per raster-scan line is thus on the order of a millisecond. A typical refresh rate of the feedback loop of 0.1 kHz to 1 kHz. The control loop thus provides updated control signals roughly for each raster-scan line. The detector system 600 is only one example. According to other examples, other types and configurations of detector systems can be employed. For instance, it would be possible to directly detect impinging electrons of the secondary beamlets using an electron to charge conversion, rather than electron to light conversion as in the illustrated example.

FIG. 7 schematically illustrates a processing device 1605. For instance, the processing device 1605 could implement at least a part of the control processor 880 of the multi-beam device 1 according to FIG. 1.

The processing device includes an FPGA 1625 that can access a corresponding memory 1630. Also, the processing device 1605 includes a microprocessor 1615 that can access a memory 1620. The processing device 1605 also includes an interface 1610 via which the

FPGA 1625 and/or the microprocessor 1615 can load data from other entities, e.g., image data acquisition unit 810, and via which the FPGA 1625 and/or the microprocessor 1615 can provide control data to other units, e.g., the control module 840 for the control of the electro-optical elements of the secondary electron imaging system 200 for applying control signals to corrective elements to stabilize the pattern of the secondary beamlets in an imaging plane (cf. FIG. 4A) towards a setpoint.

The processing device 1605 implements a closed-loop control process for stabilizing the pattern of the secondary beamlets towards a setpoint. Different sections of the closed-loop control process can be implemented by the FPGA 1625 and the microprocessor 1615, respectively. Such distribution of calculation logic between the FPGA 1625 and the microprocessor 1615 allows fast response times for calculating the control signals using the close-loop control process. In particular, fast processing is also insured for a large number of secondary beamlets.

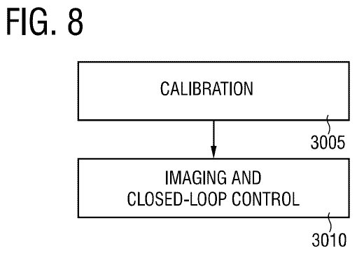

FIG. 8 is a flowchart of a method for providing closed-loop control of imaging parameters when using a multi-beam charged particle device such as an MSEM or, in particular, the multi-beam device 1 of FIG. 1.

The method of FIG. 8 can be executed by a processing device such as the processing device 1605 of FIG. 7. Parts of the method of FIG. 8 can be executed by the microprocessor 1615 in other parts of the method of FIG. 8 can be executed by the FPGA 1625.

At box 3005, a calibration process is implemented. The calibration process is used to determine one or more closed-loop parameters of the closed-loop control process. As part of the calibration process, data is collected that allows to define a setpoint used during a subsequent closed-loop control process executed while imaging at box 3010.

For example, the calibration process may be re-executed from time to time. The calibration process may be executed every time prior to startup of the multi-beam device. The calibration process could be executed repeatedly after a predetermined duration of operation of the multi-beam device.

The calibration process can take place prior to loading a sample object into the imaging device. The calibration process can sample one or more internal properties of the imaging device.

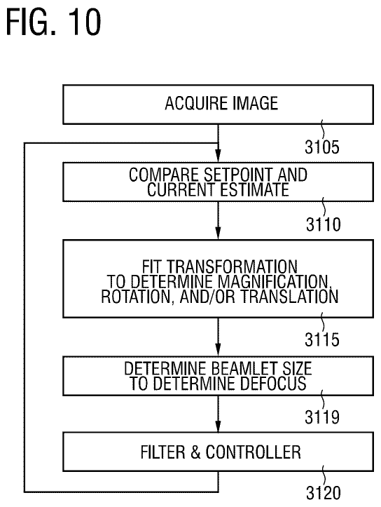

For example, the calibration process at box 3005 can include capturing one or more multi-pixel images of the secondary beamlets 9.1, 9.2, 9.3 using the multi-pixel detector 232 (cf. FIG. 5) of the detector system 600. Then, a pseudo-inverse of a transformation matrix of an affine transformation can be determined based on the one or more multi-pixel images. Details will be explained later on in further detail in connection with box 3115 in FIG. 10.

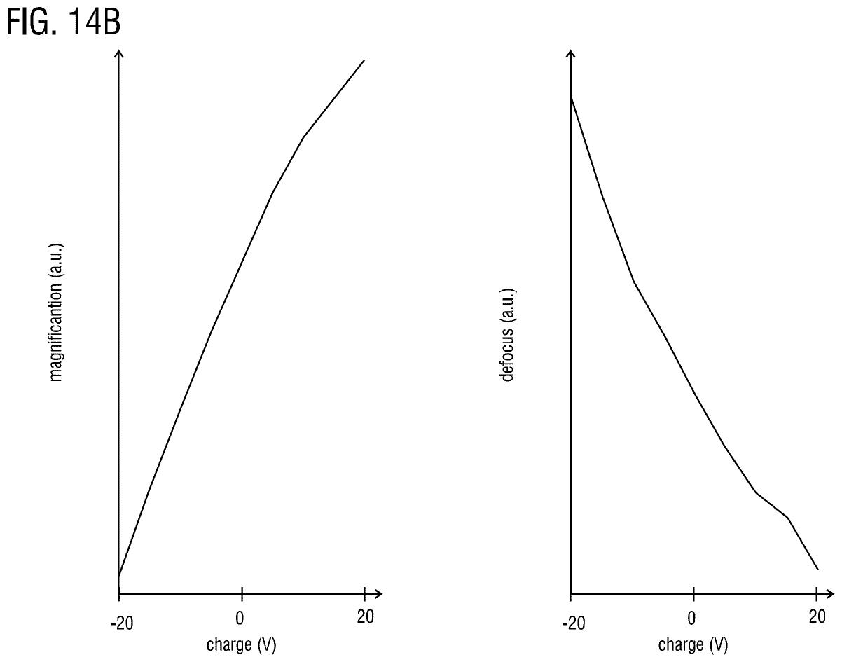

As part of the calibration process at box 3005, images of the secondary beamlets are acquired at multiple charging levels of the sample (also referred to as ‘charge-ups’ of the sample). At the multiple charging levels, both the inter-beamlet pitch as well as the defocus vary. It is possible to determine a look-up table that links the inter-beamlet pitch to defocus based on an analysis of the images (details will be explained later on in connection with FIG. 14B).

Next, at box 3010, imaging of a sample is implemented. The sample is loaded into the multi-beam device 1. The multiple primary beamlets are raster-scanned across the sample and for each raster position an image of the beamlets is acquired. Details with respect to raster-scan lines 71 have been discussed in connection with FIG. 4B. For the high-frame rate images obtained from raster scanning, the primary detector 612 is used to acquire an intensity value for each secondary beamlet 9 in each raster position. These intensity values are then combined to form an image of the sample.

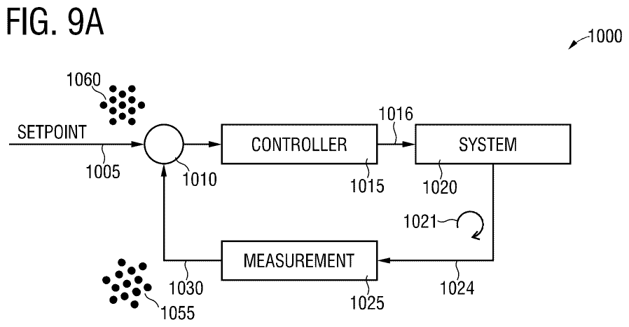

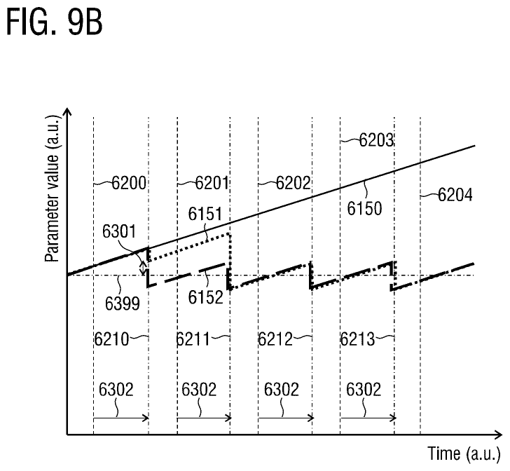

The multi-pixel detector 232 is used contemporaneously to acquire multi-pixel images at a smaller sampling rate than the primary detector 612. The multi-pixel detector 232 is not used for imaging the sample object; but rather to monitor process parameters, in particular, the pattern 41.3 of the secondary beamlets 9.1, 9.2, 9.3. The spatial resolution of the multi-pixel detector 232 is typically larger than the spatial resolution of the primary detector 612. This is why the multi-pixel detector 232 is particularly suited for monitoring the pattern 41.3. The multi-pixel images acquired using the multi-pixel detector 232 are not used for imaging the sample; but rather as part of the closed-loop control process to minimize a defocus and/or to stabilize the third pattern 41.3 of the secondary beamlets 9.1, 9.2, 9.3 in the imaging plane during imaging towards a setpoint (cf. pattern 41.3a in FIG. 4B). Details with respect to the closed-loop control process are illustrated in connection with FIG. 9A.

FIG. 9A schematically illustrates the closed-loop control process 1000. The closed-loop control process 1000 acts upon the physical system of the multi-beam device 1, represented by box 1020. More specifically, corrective elements—such as the electron-optical lenses 205.4, 205.5 or the multi-aperture plate 216 or the collective beam deflector 222—are used to stabilize the third pattern 41.3 of the secondary beamlets 9.1, 9.2, 9.3 towards a setpoint 1060 (cf. pattern 41.3b in FIG. 4B) that is predetermined and provided to a comparison unit 1010 of the closed-loop control process at 1005. For instance, the setpoint 1060 could be determined based on the pattern 41.2 formed by the primary beamlets 3.1, 3.2, 3.3 (cf. FIG. 3). Alternatively or additionally to such stabilization of the third pattern 41.3, defocus can be minimized via the closed-loop control process 1000.

To stabilize the third pattern 41.3 and/or minimize the defocus, control signals are determined at box 1015 and applied to the one or more corrective elements that then act onto the system represented by box 1020 at 1016.

For example, if a deviation of a current estimate 1055 of the pattern of the secondary beamlets from the setpoint 1060 is detected, control signals can be applied to one or more corrective elements to counteract that deviation. For instance, if a translation of the estimate 1055 away from the setpoint 1060 is detected, a counter-translation can be applied. For instance, if a rotation of the estimate 1055 with respect to the setpoint 1060 is detected, a counter-rotation can be applied. For instance, if a change of the magnification or the defocus is detected, the magnification or the defocus of the of the projection system is readjusted by adjusting the focal length of two lenses in the projection path as described in the following paragraph.

In further detail: Two magneto-or electro-static lenses with excitations I₁ und I₁ are typically available to readjust defocus and magnification (both defocus and magnification are impacted by charging of the sample). The excitations of these lenses are chosen in such way that for a zero charge level of the sample the projection image is focused and the magnification is the design value.

In a first order approximation, small changes of the excitations ΔI₁ and ΔI₂ leads to a small proportional defocus Δz and change of the magnification ΔM in the image plane:

$$Δ z = {s}_{1}^{z} Δ {I}_{1} + {s}_{2}^{z} Δ {I}_{2} \qquad ( 1 )$$

$$Δ M = {s}_{1}^{M} Δ {I}_{1} + {s}_{2}^{M} Δ {I}_{2} \qquad ( 2 )$$

The linear sensitivities

$${s}_{1 , 2}^{z}$$

and

$${s}_{1 , 2}^{M}$$

are either known from simulations or can be calibrated in a measurement (as will be explained in connection with FIG. 14B). The previous equations can be written in matrix form:

$$( \begin{matrix}Δ z \\ Δ M\end{matrix} ) = ( \begin{matrix}{s}_{1}^{z} & {s}_{2}^{z} \\ {s}_{1}^{M} & {s}_{2}^{M}\end{matrix} ) ( \begin{matrix}Δ {I}_{1} \\ Δ {I}_{2}\end{matrix} ) \qquad ( 3 )$$

Thus, if the change of magnification and defocus is known from a measurement, the desired excitation of the lenses can be calculated via matrix inversion:

$$( \begin{matrix}Δ {I}_{1} \\ Δ {I}_{2}\end{matrix} ) = {( \begin{matrix}{s}_{1}^{z} & {s}_{2}^{z} \\ {s}_{1}^{M} & {s}_{2}^{M}\end{matrix} )}^{- 1} ( \begin{matrix}Δ z \\ Δ M\end{matrix} ) \qquad ( 4 )$$

According to various examples, the calibration process 1000 is instantiated based on closed-loop control parameters that have been pre-determined in the calibration process, i.e., prior to executing the close-loop control process. This can, e.g., pertain to the setpoint 1060 or one or more operational parameters used in box 1015.

A measurement is taken at box 1025 to determine the current estimate 1055 of the pattern of the secondary beamlets 9.1, 9.2, 9.3. The measurement of box 1025 is based on an image of the secondary beamlets 9.1, 9.2, 9.3 acquired at 1024. This multi-pixel image is acquired using the multi-pixel detector 232. This current estimate 1055 is then fed to the comparison node 1010, at 1030.

Various techniques are based on the finding that it can be computationally challenging to determine the current estimate 1055 of the pattern of the secondary beamlets 9.1, 9.2, 9.3 based on the multi-pixel image. Similarly, it can be computationally challenging to determine the widths of the secondary beamlets 9.1, 9.2, 9.3. This is because the multi-pixel image typically has a large count of pixels and is processed quickly, to reduce the latency of the closed-loop control process 1000. Also, the count of secondary beamlets can be large, e.g., larger than 100 or even larger than 300. Hereinafter, techniques are disclosed that enable to determine the current estimate 1055 of the pattern of the secondary beamlets 9.1, 9.2, 9.3 at box 1025 fast and at low latency, even for large count of secondary beamlets, e.g., for more than 100 or even 500 secondary beamlets. The widths of the beamlets can be determined fast and at low latency.

As a general rule, various options are available for determining the current estimate 1055 of the pattern of the secondary beamlets 9.1, 9.2, 9.3 at box 1025 based on the multi-pixel image of the secondary beamlets. In one example, a sparse matrix multiplication is executed; the sparse matrix multiplication is between a measurement vector representing the intensity pixel values of the multi-pixel image and a sparse matrix that is predetermined in the calibration process. The sparse matrix is a closed-loop control parameter that is pre-determined in a calibration phase. The matrix multiplication with the sparse matrix can be implemented efficiently on computational hardware such as an FPGA. The sparse matrix can be pre-coded in the FPGA. In another scenario, a difference image can be determined between a reference image that represents the setpoint 1060 and the image acquired at 1024 for a given iteration 1021 of the closed-loop control process 1000, the difference image is rearranged as a one dimensional vector which is the multiplied with a precomputed matrix. Also, such difference image and matrix multiplication can be efficiently calculated. Details with respect to such techniques of implementing box 1025, the comparison node 1010 etc. will be explained further below in connection with FIG. 10.

A similar technique can also be used to determine width o of the beam spots. This allows to estimate the defocus of the image. Details will be explained further below.

The closed-loop control process 1000 also includes the controller section at box 1015. Here, the appropriate control signals to be applied to the one or more corrective elements that act, at 1016 upon the physical system 1020, are determined based on the output from the comparison node 1010. Firstly, it is possible to apply control signals to one or more corrective elements to compensate for a rotation and/or a translation and/or magnification and/or defocus and/or distortion and/or astigmatism and/or other aberrations between the current estimate 1055 and the setpoint 1060.

According to examples, the rotation and/or the translation and/or the magnification are determined based on transformation parameters of an affine transformation. The affine transformation is determined based on a difference between the setpoint 1060 and the current estimate 1055 of the pattern of the secondary beamlets. The transformation parameters of the affine transformation are used to determine the control signals to be applied to the one or more corrective elements.

As a general rule, an affine transformation preserves lines and parallel arrangement between lines, but not necessarily Euclidean distances and angles. The affine transformation can be represented by a translation and a linear map.

As a general rule, it would be possible that the section of the closed-loop control process 1000 corresponding to box 1025—i.e., determining the current estimate 1055 of the pattern of the secondary beamlets and/or determining defocus—is implemented at least partly by FPGA logic such as the FPGA 1625 of the computing device 1605. It has been found that by using the appropriate techniques for determining the current estimate 1055 of the pattern of the secondary beamlets, and efficient implementation on the FPGA logic is possible. In particular, low-latency calculation of the current estimate 1055 is possible, even for large number of secondary beamlets.

On the other hand, a section of the closed-loop control process 1000 that determines the affine transformation—i.e., box 1015—can be implemented by a microprocessor such as the microprocessor 1615 of the computing device 1605. By splitting the logic of the closed-loop control process 1000 between the FPGA and the microprocessor, on the one hand low latency and fast computation is possible; on the other hand, flexibility in the programming is preserved by using the microprocessor.

In some examples, the transformation parameters of the affine transformation that are determined at box 1015 based on the output of the comparison node 1010 of the given iteration 1021 are directly used to determine the control signals for one or more corrective elements to act upon the system 1020 at 1016 of the next iteration 1021. In other scenarios, a recursive filter such as a Kalman filter is employed to filter these signals; the recursive filter takes into account an evolution of the outputs of the comparison node 1010 across multiple iterations 1021 as well as a state transition model for the system 1020.

Furthermore, in some examples, the controller at box 1015 can also extrapolate magnification, rotation and/or translation derived from the current estimate 1055 and the output of the comparison node 1010 of the current iteration 1021 to a future point in time. This can be based on the evolution of the current estimate 1055 across multiple iterations 1021. A linear or non-linear extrapolation can be used. For instance, an empirical model of the time-dependence of the magnification change derived from experimental data for a specific sample type can be used. This would then effectively be a predetermined voltage curve applied to the corrective elements combined with live adjustments for finetuning. This is illustrated in FIG. 9B.

FIG. 9B illustrates the time dependency of an example parameter of the secondary beamlets—e.g., magnification, rotation, distortion, translation, defocus, etc.-without any closed-loop control (full line 6150), with the close-loop control process 1000 without extrapolation (dotted line 6151), as well as employing the close-loop control process 1000 using extrapolation of the respective estimate of the parameter (dashed line 6152).

FIG. 9B illustrates respective time dependencies. FIG. 9B illustrates that multiple iterations 1021 of the close-loop control process 1000 are executed repeatedly. In particular, at timepoints 6200, 6201, 6202, and 6203, measurements of the current estimate of the respective parameter taken (corresponding to box 1025).

At timepoints 6210, 6211, 6212, and 6213, control signals are applied to compensate for any deviations from the setpoint value 6399 of that parameter (horizontal dashed-dotted line), i.e., corresponding to box 1015.

As will be appreciated from FIG. 9B, there is a time offset 6302 between taking respective measurements at one of the timepoints 6200, 6201, 6202, and 6203 and applying the respective control signal at one of the timepoints 6210, 6211, 6212, and 6213. Due to this time offset 6302, e.g., the actual deviation at timepoint 6210 is underestimated by the observation taken at timepoint 6200 (this deviation 6301 is illustrated in FIG. 9B).

Accordingly, the parameter value is not stabilized to the setpoint 6399 for the non-extrapolating scenario (dotted line 6151). Within extrapolation, based on the deviation 6301 observed at timepoint 6200, a larger control offset is applied at timepoint 6210 and the parameter values stabilized closer to the setpoint 6399 at timepoint 6210 (as illustrated by the dashed line 6152).

FIG. 10 is a flowchart of various examples. FIG. 10 illustrates a method of implementing a closed-loop control process for stabilizing a pattern of secondary beamlets towards a setpoint. The method of FIG. 10 can implement the closed-loop control process 1000 of FIG. 9A.

First, at box 3105, a multi-pixel image of the secondary beamlets 9.1, 9.2, 9.3 is acquired. This can be done by appropriately controlling and reading out the multi-pixel detector 232 (cf. FIG. 6). This implements branch 1024 of the closed-loop control process 1000.

Then, at box 3110, the positions of the beam centers 15 of the secondary beamlets in the multi-pixel image are determined. This corresponds to determining the current estimate 1055 of the pattern of the secondary beamlets 9.1, 9.2, 9.3. Furthermore, beam widths of the secondary beamlets in the multi-pixel image are determined in some scenarios (i.e., the size of the secondary beamlets is determined).

Accordingly, box 3110 in one option implements the section of the closed-loop control process 1000 associated with box 1025 (cf. FIG. 9A). Box 3110 can thus be implemented at least partly by the FPGA 1625.

One example approach for determining the positions of the beam centers 15 (this corresponds to determining the inter-beamlet pitch) is explained next in detail (for an example scenario of J=91 secondary beamlets, but this may be equally applied to other values of J).

The multi-pixel image with N pixels can be represented by a 1-D vector (measurement vector):

$$\vec{I} \to = [ \begin{matrix}{I}_{1} \\ … \\ {I}_{N}\end{matrix} ] \qquad ( 5 )$$

Here, I₁. . . I_{N} are the pixel intensity values.

Furthermore, for each pixel the corresponding x-and y-coordinates are given by

$$\overline{x} = [ \begin{matrix}{x}_{1} \\ … \\ {x}_{N}\end{matrix} ] , \overline{y} = [ \begin{matrix}{y}_{1} \\ … \\ {y}_{N}\end{matrix} ] \qquad ( 6 )$$

Then, pixel clusters (also referred to as region of interest, ROI) are defined. The pixel clusters are defined such that one and only one secondary beamlet is located in each pixel cluster. The pixel clusters would normally correspond to the mFOVs 72. The pixel clusters can be described by a 91×N matrix:

$${ROI}_{k , l} = \{ \begin{matrix}1 & if pixel l ∈ ROI k \\ 0 & otherwise\end{matrix} \qquad ( 7 )$$

If the pixel clusters do not overlap, the matrix [symbol] is sparse. i.e., it has N or less non-zero elements.

These pixel clusters are defined in the calibration process. The pixel clusters can be defined by manually segmenting or structuring a reference image taken without a sample being present. The pixel cluster thus define prior knowledge regarding the coarse arrangement of the secondary beamlets.

This sparse matrix [symbol] selects the particular pixel clusters.

One can define sparse matrices \hat{X}, Ý by:

$$\hat{X} = [ \begin{matrix}{x}_{1} {ROI}_{1 , 1} & … & {x}_{N} {ROI}_{N , 1} \\ & … & \\ {x}_{1} {ROI}_{1 , 91} & … & {x}_{N} {ROI}_{N , 91}\end{matrix} ] \qquad ( 8 )$$

$$\hat{Y} = [ \begin{matrix}{y}_{1} {ROI}_{1 , 1} & … & {y}_{N} {ROI}_{N , 1} \\ & … & \\ {y}_{1} {ROI}_{1 , 91} & … & {y}_{N} {ROI}_{N , 91}\end{matrix} ]$$

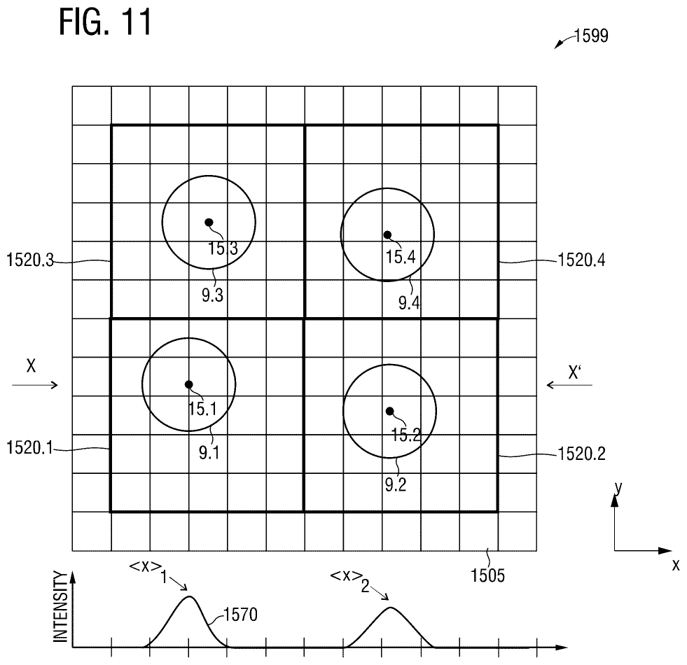

FIG. 11 illustrates the pixels 1505 of a multi-pixel image 1599 acquired using the multi-pixel detector 232. Illustrated are also the pixel clusters 1520.1, 1520.2, 1520.3, 1520.4 (bold lines). Also illustrated are the secondary beamlets 9.1, 9.2, 9.3, 9.4 and the respective centers 15.1, 15.2, 15.3, 15.4. Also illustrated is the intensity 1570 of the pixels that can be expressed by \vec{I} (along the line X-X′).

It is then possible to calculate the position of the local maximum of the pixel intensities within each pixel cluster 1520.1, 1520.2, 1520.3, 1520.4.

The x-position of center within the ROI k is given by:

$$x {k}_{} = \frac{{\sum }_{n = 1 … N} {x}_{n} {ROI}_{n , k} {I}_{n}}{{\sum }_{n = 1 … N} {ROI}_{n , k} {I}_{n}} = \frac{{( \hat{X} \cdot \vec{I} )}_{k}}{{( \cdot \vec{I} )}_{k}} . \qquad ( 9 )$$

And analogously the y-position:

$${〈 y 〉}_{k} = \frac{{\sum }_{n = 1 … N} {y}_{n} {ROI}_{n , k} {I}_{n}}{{\sum }_{n = 1 … N} {ROI}_{n , k} {I}_{n}} = \frac{{( \hat{Y} \cdot \vec{I} )}_{k}}{{( \cdot \vec{I} )}_{k}} . \qquad ( 10 )$$

Accordingly, calculating the centers 15.1, 15.2, 15.3, 15.4 of all secondary beamlets 9.1, 9.2, 9.3, 9.4 includes:

First, prepare sparse matrices [symbol] , X, Y. This processing step can be done during calibration (cf. box 3005) i.e., outside of the feedback loop of the closed-loop control process 1000. Therefore, these calculations are not time critical. To position the pixel clusters 1520.1, 1520.2, 1520.3, 1520., the calculation involves the design position of the secondary beamlets 9.1, 9.2, 9.3, 9.4 and/or a reference image of the secondary beamlets 9.1, 9.2, 9.3, 9.4.

Second, within the feedback loop, calculate the integrated intensity in each pixel cluster via sparse matrix multiplication:

$${\vec{I}}_{meas} = \cdot \vec{I} \qquad ( 11 )$$

Third, determine the center in the x-direction via matrix multiplication of the sparse matrix that selects the pixel clusters and the measurement vector and element-wise division:

$${\vec{x}}_{meas} = \frac{\hat{X} \cdot \vec{I}}{{\vec{I}}_{roi}} \qquad ( 12 )$$

$${\vec{y}}_{meas} = \frac{\hat{Y} \cdot \vec{I}}{{\vec{I}}_{roi}} \qquad ( 13 )$$

\vec{x}ₘₑₐₛ and \vec{y}ₘₑₐₛ can be concatenated in a single vector \vec{r}ₘₑₐₛ defining the center positions:

$${\vec{r}}_{m e a s} = [ \begin{matrix}{\vec{x}}_{meas} \\ {\vec{y}}_{meas}\end{matrix} ] \qquad ( 14 )$$

The approach described above can also be used to estimate the width of the secondary beamlets by estimating the variance within each pixel cluster along the×and y-axis respectively. This is used for determining the defocus. The variance of the k-th pixel cluster can be written as:

$$Δ {x}_{k}^{2} = {x}^{2} {k}_{} - {x}^{2} {k}_{2}^{} = \frac{{( \cdot \vec{I} )}_{k}}{{( \cdot \vec{I} )}_{k}^{2}} - \frac{{( \hat{X} \cdot \vec{I} )}_{k}^{2}}{{( \cdot \vec{I} )}_{k}^{2}} \qquad ( 15 )$$

Where [symbol] is also a sparse matrix.

$$= [ \begin{matrix}{x}_{1}^{2} {ROI}_{1 , 1} & … & {x}_{N}^{2} {ROI}_{N , 1} \\ & … & \\ {x}_{1}^{2} {ROI}_{1 , 91} & … & {x}_{1}^{2} {ROI}_{N , 91}\end{matrix} ] . \qquad ( 16 )$$

It is possible to determine the variance and covariance of each pixel cluster:

$${Δ y}_{k}^{2} = {y}^{2} {k}_{} - y {k}_{2}^{} \qquad ( 17 )$$

$${Δ xy}_{k} = xy {k}_{} - x {k}_{} y {k}_{}$$

Referring again to FIG. 10, once the center positions of the secondary beamlets have been determined, the current estimate 1055 is known. Then, at box 3115 an affine transformation is fitted that transforms between (a) the setpoint 1060 of the pattern and (b) the current estimate 1055 of the pattern of secondary beamlets 9—that is expressed by the positions of the centers 15, see (14), and optionally the width of the beams—cf. (17)—, as outlined in in box 3110.

The transformation parameters define magnification, shift and rotation of the current estimate 1055 of the pattern and the setpoint 1060.

Magnification, rotation, and shift can be described by the following linear affine transformation from the nominal center position Tref of the setpoint 1060 and the measurement position Tmeas:

$${\vec{r}}_{m e a s} = [ \begin{matrix}M cos ϕ & - M sin ϕ \\ M sin ϕ & M cos ϕ\end{matrix} ] \cdot {\vec{r}}_{ref} + \vec{Δ} = [ \begin{matrix}{M}_{c} & - {M}_{s} \\ {M}_{s} & {M}_{c}\end{matrix} ] \cdot {\vec{r}}_{ref} + \vec{Δ} \qquad ( 18 )$$

Here, it is assumed that the magnification changes in the same manner in the two orthogonal lateral directions of the imaging plane. This assumption corresponds to an assumption of zero distortion. It would however also be possible to consider different magnification changes for the two orthogonal lateral directions of the imaging plane, thereby modeling distortion.

Equation (18) can be re-written as

$$[ \begin{matrix}{x}_{1} \\ … \\ {x}_{\text{?}} \\ {y}_{1} \\ … \\ {y}_{\text{?}}\end{matrix} ] \approx [ \begin{matrix}{X}_{1} & - {Y}_{1} & 1 & 0 \\ … & … & … & … \\ {X}_{91} & - {Y}_{91} & 1 & 0 \\ {Y}_{1} & {X}_{1} & 0 & 1 \\ … & … & … & … \\ {Y}_{91} & {X}_{91} & 0 & 1\end{matrix} ] \cdot [ \begin{matrix}{M}_{\text{?}} \\ {M}_{\text{?}} \\ {Δ}_{x} \\ {Δ}_{y}\end{matrix} ] = \cdot [ \begin{matrix}{M}_{\text{?}} \\ {M}_{\text{?}} \\ {Δ}_{x} \\ {Δ}_{y}\end{matrix} ] \qquad ( 19 )$$

$$\text{?} \text{indicates text missing or illegible when filed}$$

Here, the linear affine transformation is rewritten in a conventional manner as a single matrix multiplication using the augmented vector on the right-hand side including both the linear map (M_{c}, Mₛ) as well as the translation properties (Δₓ, Δ_{y}).

Since it only depends on \vec{r}_{ref}, the matrix [symbol] is predefined. The vector on the right hand side of (19) contains the transformation parameters. Because the measurement has uncertainties and there might be additional distortion terms not described by the previous simple model (e.g., different magnification in x-and y-direction or non-linear distortion terms) the equal sign in (19) by an approximately equal. The problem can thus be treated as a linear least-square fitting problem. I.e., the transformation parameters of the affine transformation can be determined using a least square fit.

The goal is to find the transformation parameters M_{c}, Mₛ, Δₓ, Δ_{y} that minimize the difference between the measured vector on the left-hand side and the fitted vector on the right hand side in a least-square sense.

The least square fit is applied using the More-Penrose pseudo inverse matrix of

[symbol]

$$[ \begin{matrix}{M}_{\text{?}} \\ {M}_{\text{?}} \\ {Δ}_{x} \\ {Δ}_{y}\end{matrix} ] = pinv ( ) \cdot [ \begin{matrix}{x}_{1} \\ … \\ {x}_{\text{?}} \\ {y}_{1} \\ … \\ {y}_{\text{?}}\end{matrix} ] \qquad ( 20 )$$

$$\text{?} \text{indicates text missing or illegible when filed}$$

The inverse matrix pinv( [symbol] ) can be pre-computed during the calibration. It depends on the setpoint 1060. This matrix can be determined base on a reference image acquired during calibration. The center positions of the beamlets could be manually annotated or extracted automatically, to determine this matrix.

The magnification and rotation are then calculated based on the transformation parameters via

$$M = \sqrt{{M}_{s}^{2} + {M}_{c}^{2}}$$

and ϕ=arctan

$$( \frac{M s}{M c} ) .$$

Shift/translation is directly given as Δₓ, Δ_{y}.

Above, a linear affine transformation has been disclosed. However, the described fitting procedure can also be used to fit non-linear transformations. For example, to fit an arbitrary affine transformation with four degrees of freedom and a shift the least square problem reads:

$$[ \begin{matrix}{x}_{1} \\ … \\ {x}_{91} \\ {y}_{1} \\ … \\ {y}_{91}\end{matrix} ] \approx [ \begin{matrix}{X}_{1} & {Y}_{1} & 0 & 0 & 1 & 0 \\ … & … & … & … & … & … \\ {X}_{91} & {Y}_{91} & 0 & 0 & 1 & 0 \\ 0 & 0 & {X}_{1} & {Y}_{1} & 0 & 1 \\ … & … & … & … & … & … \\ 0 & 0 & {X}_{91} & {Y}_{91} & 0 & 1\end{matrix} ] \cdot [ \begin{matrix}{M}_{xx} \\ {M}_{xy} \\ {M}_{yx} \\ {M}_{yy} \\ {Δ}_{x} \\ {Δ}_{y}\end{matrix} ] \qquad ( 21 )$$

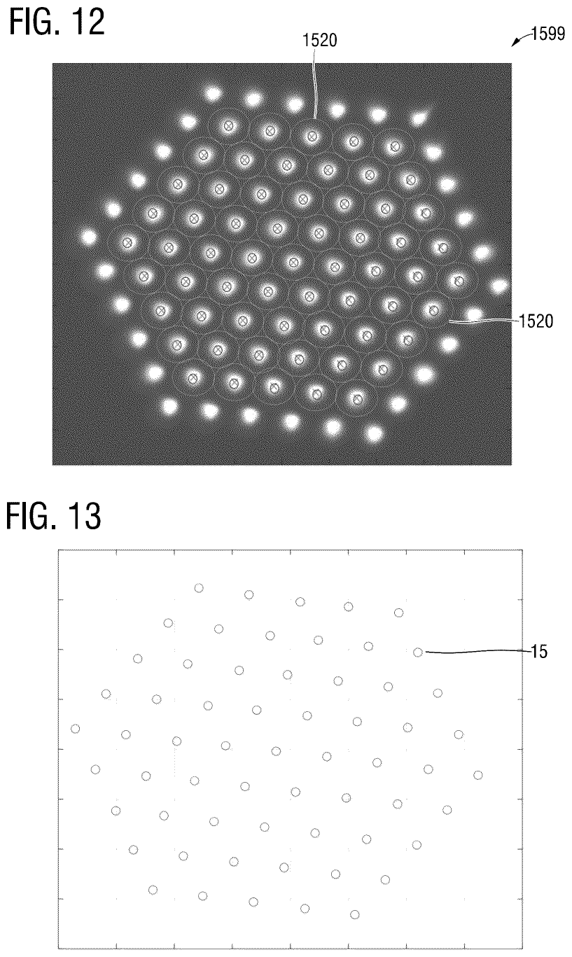

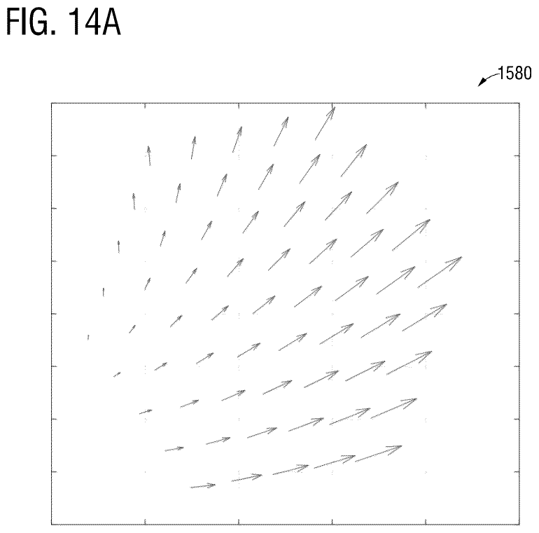

The determining of the positions of the sensors of the secondary beamlets and the fitting of the linear affine transformation are also illustrated in connection with FIG. 12, FIG. 13, and FIG. 14A. In FIG. 12, the grayscale illustrates the intensity pixel values of the detector for a multi-pixel image of the plurality of secondary beamlets. The large circles illustrate the pixel clusters 1520, the crosses is illustrate the centers 15 of the secondary beamlets 9, and the small circles illustrate the centers of the reference pattern according to the setpoint 1060. FIG. 13 then illustrates only the centers 15 of the secondary beamlets 9 determined using (9) and (10). FIG. 14A illustrates the impact (linear map plus translation) of the linear affine transformation 1580 determined using the least-square fit of the transformation parameters according to (20).

The above-identified approach of initially determining the centers 15 of the secondary beamlets 9 using the multiplication with the sparse matrix that selects the respective pixel clusters and then fitting the linear affine transformation is only one option to implement the determination of the magnification, rotation, and translation.

As explained above, the closed-loop control process 1000 cannot only be used for stabilizing the pattern 41.3 of the secondary beamlets towards the setpoint 1060; alternatively or additionally, it is also possible to use the close-loop control process 1000 to minimize defocus.

The defocus is determined from the calculated variances, at box 3119. More specifically, the absolute value of the defocus is determined from the sizes of the secondary beamlets. The width of each beamlet is given by:

$${σ}_{k} = \sqrt{Δ {x}_{k}^{2} + Δ {y}_{k}^{2}} \qquad ( 22 )$$

A mean beam width is calculated by averaging over all beams:

$$σ = \frac{1}{N} {\sum }_{k = 1 … N} {σ}_{k} \qquad ( 23 )$$

The width has a minimum in the best focus and increases quadratically for a small defocus:

$$σ ( z ) \approx {σ}_{0} + {S}_{σ} {z}^{2} \qquad ( 24 )$$

The sensitivity S_{σ} can obtained from simulations or measured. Thus, the change of the beam width allows calculating the absolute value of the defocus.

$$\vert z \vert \approx \sqrt{\frac{σ ( z ) - {σ}_{0}}{{S}_{σ}}} \qquad ( 25 )$$

The closed-loop control process accordingly includes minimizing the defocus of the secondary beamlets based on this size of the secondary beamlets.

To determine the sign (i.e., direction) of the defocus one can make use of the fact that the defocus and change of magnification induced by the charging of the sample are correlated. Accordingly, the direction of the defocus can be determined based on the inter-beamlet pitch. This is illustrated in FIG. 14B which shows in the observed change of the magnification (left; corresponding to the inter-beamlet pitch) and defocus (right) as a function of the amount of charging of the sample (i.e., as a function of the charging level). This enables determining the sign of the change of the defocus from the magnification change: An increasing magnification corresponds to a negative defocus and vice versa. The slope of FIG. 14B, right corresponds to the sensitivity S_{σ}. During calibration, a lookup table can be determined. The look-up table determines the direction of the defocus depending on the inter-beamlet pitch (i.e., the magnification).

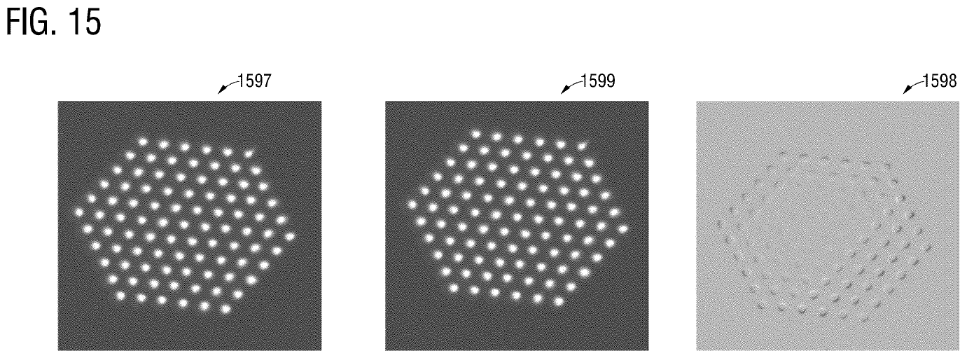

Above, a scenario of implementing a comparison of the setpoint 1060 with the current estimate 1055 of the pattern of the secondary beamlets to stabilize the pattern of the secondary beamlets has been disclosed in connection with box 3110 and box 3115. Other variants for implementing such comparison are possible. One further variant will be explained below. A further scenario to compare the setpoint 1060 with the current estimate 1055, i.e., another option for determining box 3110, is illustrated in connection with FIG. 15.

In particular, FIG. 15, left, illustrates a reference image 1597 of the secondary beamlets acquired during the calibration (cf. box 3005). Accordingly, this reference image 1597 is associated with the setpoint 1060 of the pattern of the secondary beamlets. Further, FIG.

15, middle, illustrates the image 1599 of the secondary beamlets acquired at box 3105, i.e., as indicative of the current pattern of the secondary beamlets. Finally, FIG. 15, right side illustrates a difference image 1598 (determined by a pixel-by-pixel difference) between the reference image and the current image of the secondary beamlets.

The relationship between the measured image I(\vec{r}, t) and the reference image I₀(\vec{r}, t) is given by:

$$I ( \vec{r} , t ) = {I}_{o} ( \vec{r} + δ \vec{r} ( \vec{r} , t ) ) \approx {I}_{o} ( \vec{r} ) + \vec{∇} {I}_{o} ( \vec{r} ) δ \vec{r} ( \vec{r} , t ) \qquad ( 26 )$$

This corresponds to a linear approximation of the change of the reference image: under the assumption of a linear affine transformation the change can be expressed as:

$$δ \vec{r} ( \vec{r} , t ) = \vec{Δ r} + ( \begin{matrix}{M}_{xx} & {M}_{xy} \\ {M}_{yx} & {M}_{yy}\end{matrix} ) \vec{r} \qquad ( 27 )$$

Here, Mₓₓ=M_{yy} and M_{xy}=M_{yx}=0 would correspond to a zero-distortion scenario. The difference image yields

$$Δ I ( \vec{r} , t ) = I ( \vec{r} , t ) - {I}_{o} ( \vec{r} , 0 ) \approx \vec{∇} {I}_{o} ( \vec{r} , 0 ) δ \vec{r} ( \vec{r} , t ) = \vec{∇} {I}_{o} ( \vec{r} , 0 ) \vec{Δ r} + \vec{∇} {I}_{o} ( \begin{matrix}{M}_{xx} & {M}_{xy} \\ {M}_{yx} & {M}_{yy}\end{matrix} ) \vec{r} \qquad ( 28 )$$

which can be rewritten as:

$$Δ I ( \vec{r} , t ) \approx {\partial }_{x} {I}_{o} ( \vec{r} , 0 ) {Δ}_{x} + {\partial }_{y} {I}_{o} ( \vec{r} , 0 ) {Δ}_{y} + {\partial }_{x} {I}_{o} ( \vec{r} , 0 ) {M}_{x x} x + {\partial }_{x} {I}_{o} ( \vec{r} , 0 ) {M}_{x y} y + {\partial }_{y} {I}_{o} ( \vec{r} , 0 ) {M}_{y x} x + {\partial }_{y} {I}_{o} ( \vec{r} , 0 ) {M}_{y y} y \qquad ( 29 )$$

and in matrix notation

$$( \begin{matrix}Δ {I}_{1} \\ … \\ Δ {I}_{N}\end{matrix} ) \approx ( \begin{matrix}{\partial }_{x} {I}_{o 1} & {\partial }_{y} {I}_{o 1} & x {\partial }_{x} {I}_{o 1} & y {\partial }_{x} {I}_{o 1} & x {\partial }_{y} {I}_{o 1} & y {\partial }_{y} {I}_{o 1} \\ … & … & … & … & … & … \\ {\partial }_{x} {I}_{o N} & {\partial }_{y} {I}_{o 1} & x {\partial }_{x} {I}_{o 1} & y {\partial }_{x} {I}_{o 1} & x {\partial }_{y} {I}_{o 1} & y {\partial }_{y} {I}_{o 1}\end{matrix} ) ( \begin{matrix}{Δ}_{x} \\ {Δ}_{y} \\ {M}_{xx} \\ {M}_{x y} \\ {M}_{y x} \\ {M}_{yy}\end{matrix} ) \qquad ( 30 )$$

This again corresponds to a least square fit (cf. box 3115):

$$m {i}_{\vec{c}} n {\vert Δ \vec{I} - LSQ \cdot \vec{c} \vert}^{2} \qquad ( 31 )$$

that can be implemented by the pseudo-inverse:

$$\vec{c} = pinv ( LSQ ) \cdot Δ \vec{I} \qquad ( 32 )$$

Accordingly, instead of determining the centers of the secondary beamlets by selecting the pixel clusters using the sparse matrix it is possible to determine the difference image and then apply the matrix multiplication with the pseudo-inverse of the least-square matrix according to

$$\vec{c} = pinv ( LSQ ) \cdot Δ \vec{I} \qquad ( 32 )$$

This also yields the transformation parameters. Again, the pseudo-inverse of the least-square matrix can be determined during calibration, because it only depends on the reference pattern of the secondary beamlets according to the setpoint 1060.

Irrespective of the particular technique (e.g., using the pixel clusters as in FIG. 11 or the difference image as in FIG. 15), the transformation parameters of the affine transformation are obtained; and, from this, magnification, rotation and translation can be determined at box 3115.

Then referring again to FIG. 10, at box 3120, a filter can be applied. More specifically, a recursive filter can be applied. The recursive filter can be used to refine the magnification, translation, and rotation of box 3115 based on the current estimate 1055 and an evolution of this estimate 1055 across multiple iterations 1021 of the closed-loop control process 1000. The filter can consider a model for the change of the transformation parameters from iteration 1021 to iteration 1021.

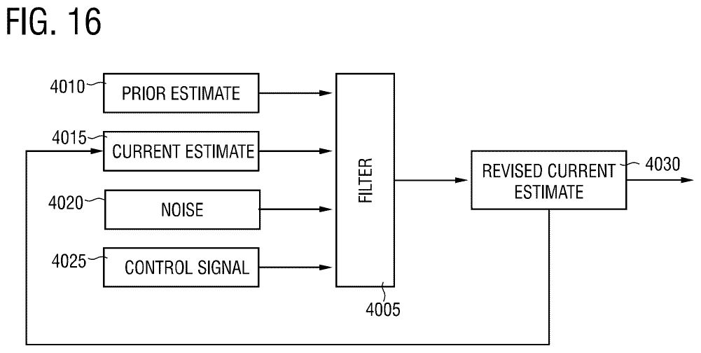

FIG. 16 schematically illustrates the filter 4005. The filter 4005 obtains one or more values indicative of the current estimate 1055 of the pattern of the secondary beamlets at box 5010 (e.g., the transformation parameters of the linear affine transformation), one or more values indicative of one or more prior estimates 1055 (i.e., from preceding iterations 1021 of the closed-loop control process 1000) at box 4010, an estimate of the noise at box 4020, and the previous control signals at box 4025. The filter 4005 then provides one or more values indicative of a revised estimate of the pattern of the secondary beamlets at box 4030 (e.g., the revised transformation parameters).

An example will be described in which the recursive filter is implemented by a Kalman filter.

The Kalman filter recursively estimates the current state of a system (here: the transformation parameters) by predicting the current state from a prior state using a physical model, comparing this predicted state to a measurement (if available) and taking into account control inputs which changed the system.

In detail, each iteration of the filter includes a prediction step and (if a measurement is available) an update step. To start with, the system is described by a vector xₖ of length n at each timestep k. The process noise is described by a vector wₖ of length n. If the system has control inputs, then a vector uₖ of length m describes these inputs. Also, one has to find n×n-matrices Fₖ and n×m-matrices Bₖ such that at each timestep

$${x}_{k} = {F}_{k} {x}_{k - 1} + {B}_{k} {u}_{k} + {w}_{k} . \qquad ( 33 )$$

One can thus think of Fₖ as the state transition model and of Bx as the control-input model (translating a control input into its effect on the system state). The vector wₖ is assumed to be drawn from a normal distribution with covariance Qₖ (n×n-matrix). Only this matrix Qₖ and not the vector wₖ is involved in the prediction and update steps. The measurement process is described by a p×n-matrix Hₖ and a vector νₖ of length p describing the measurement noise according to

$${z}_{k} = {H}_{k} {x}_{k} + {v}_{k} \qquad ( 34 )$$

with the measurement result being the vector zₖ (of length p). The vector νₖ is assumed to be drawn from a normal distribution with covariance Rₖ (p×p-matrix).

The model is initialized with some state x_{0|0}, the certainty of knowing this initial state is described by the initial covariance matrix P_{0|0}. In the prediction step, an a priori state estimate is defined as

$${\hat{x}}_{k \vert k - 1} = {F}_{k} {x}_{k - 1 \vert k - 1} + {B}_{k} {u}_{k} \qquad ( 35 )$$

and the a priori estimate covariance is

$${\hat{P}}_{k \vert k - 1} = {F}_{k} {P}_{k - 1 \vert k - 1} {F}_{k}^{T} + {Q}_{k} . \qquad ( 36 )$$

In the update step, with measurement zₖ, the measurement pre-fit residual is

$${\tilde{y}}_{k} = {z}_{k} - {H}_{k} {\hat{x}}_{k \vert k - 1} \qquad ( 37 )$$

and the pre-fit residual covariance is

$${S}_{k} = {H}_{k} {\hat{P}}_{k \vert k - 1} {H}_{k}^{T} + {R}_{k} . \qquad ( 38 )$$

The optimal Kalman gain (balancing the predicted state to the measured state) is

$${K}_{k} = {\hat{P}}_{k \vert k - 1} {H}_{k}^{T} {S}_{k}^{- 1} . \qquad ( 39 )$$

This gives the a posteriori state estimate of

$${x}_{k \vert k} = {\hat{x}}_{k \vert k - 1} + {K}_{k} {\tilde{y}}_{k} \qquad ( 40 )$$

And it's a posteriori estimate covariance

$${P}_{k \vert k} = {\hat{P}}_{k \vert k - 1} - {K}_{k} {H}_{k} {\hat{P}}_{k \vert k - 1} . \qquad ( 41 )$$

The post-fit residual is

$${\tilde{y}}_{k \vert k} = {z}_{k} - {H}_{k} {x}_{k \vert k} . \qquad ( 42 )$$

Now applying this to the closed-loop control process 1000: a simplified model of the state of the system is given by

$$x = ( \begin{matrix}mag \\ \dot{mag} \\ foc \\ \dot{foc}\end{matrix} ) \qquad ( 43 )$$

This corresponds to M, cf. (27) for Mₓₓ=M_{yy} and M_{xy}=M_{yx}=0: In this scenario, a simplified model is considered. Only magnification and defocus are controlled (rotation and translation and distortion are not considered). However, it is straightforward to consider other parameters describing the deviation of the current pattern of secondary beamlets from the set point, e.g., rotation and translation or even distortion.

Hence, foc denotes the distance of the plane of the best focus to the detector plane and mag denotes the relative deviation of the actual pitch at the detector plane from the ideal pitch. m\dot{a}g and f\dot{o}c denote the derivatives of these respective values by time. The state transition model is

$$F = ( \begin{matrix}1 & Δ t & 0 & 0 \\ 0 & 1 & 0 & 0 \\ 0 & 0 & 1 & Δ t \\ 0 & 0 & 0 & 1\end{matrix} ) \qquad ( 44 )$$

where Δt denotes the time between the current timestep and the previous one (possibly not constant), i.e., time delay from iteration to iteration 1021. The control input is the readjustment done to the corrective elements, i.e., given by the control signals applied to the one or more corrective elements:

$$u = ( \begin{matrix}Δ C 1 \\ Δ C 2\end{matrix} ) \qquad ( 45 )$$

and the control input includes of the sensitivity matrix of the corrective elements on magnification and focus, i.e.

$$B = ( \begin{matrix}{sens}_{11} & {sens}_{12} \\ 0 & 0 \\ {sens}_{21} & {sens}_{22} \\ 0 & 0\end{matrix} ) for sens = ( \begin{matrix}\frac{dmag}{dC 1} & \frac{dmag}{dC 2} \\ \frac{dfoc}{dC 1} & \frac{dfoc}{dC 2}\end{matrix} ) . \qquad ( 46 )$$

As a model for the process noise several choices are possible. One possibility is to assume that due to some uncontrolled inputs (noise of the lens excitations, local properties of the sample, . . . ) m\dot{a}g and f\dot{o}c (or m\dot{a}g and f\dot{o}c themselves) change. For simplicity, first assume that m\dot{a}g and f\dot{o}c may be changed. If they change independently, one has

$$w = ( \begin{matrix}{G}_{\dot{mag}} \cdot {a}_{\dot{mag}} \\ {G}_{\dot{foc}} \cdot {a}_{\dot{foc}}\end{matrix} ) with {G}_{\dot{mag}} = {G}_{\dot{foc}} = ( \begin{matrix}Δ t \\ 1\end{matrix} ) \qquad ( 47 )$$

with α_{m\dot{a}g} and α_{f\dot{o}c}being drawn from a normal distribution with standard deviations σ_{α,m\dot{a}g} and σ_{α,f\dot{o}c}respectively. The covariance matrix Q would then read

$$Q = ( \begin{matrix}{G}_{\dot{mag}} {G}_{\dot{mag}}^{T} \cdot {σ}_{a , \dot{mag}}^{2} & 0 \\ 0 & {G}_{\dot{foc}} {G}_{\dot{foc}}^{T} \cdot {σ}_{a , \dot{foc}}^{2}\end{matrix} ) . \qquad ( 48 )$$

If the noise of m\dot{a}g and f\dot{o}c is not independent but m\dot{a}g and f\dot{o}c change according to a fixed conversation factor c_{mag/foc} then one may also assume

$$w = G \cdot a with G = ( \begin{matrix}Δ t \\ 1 \\ Δ t / {c}_{mag / foc} \\ 1 / {c}_{mag / foc}\end{matrix} ) \qquad ( 49 )$$

where a is being drawn from a normal distribution with standard deviation σ_{α}. The covariance matrix Q would then read

$$Q = G \cdot {G}^{T} \cdot {σ}_{a}^{2} . \qquad ( 50 )$$

If instead of m\dot{a}g and f\dot{o}c the values of mag and foc are directly changed by the process noise, then G has the form

$$G = ( \begin{matrix}1 \\ 0\end{matrix} ) \qquad ( 51 )$$

instead.

Considering the measurement process box 4015, only the magnification change is measured (cf. Eq. 10), so that

$$H = ( 1000 ) . \qquad ( 52 )$$

If also the defocus is measured (at least at some iterations) the matrix H would read

$$H = ( \begin{matrix}1000 \\ 0010\end{matrix} ) \qquad ( 53 )$$

in those iterations.

Regarding noise (box 4020): In the former case, Gaussian measurement noise is assumed with standard deviation σ_{z} such that

$$R = {σ}_{z}^{2} . \qquad ( 54 )$$

In the latter case, independent Gaussian measurement noise of pitch change and defocus can be assumed to yield:

$$R = ( \begin{matrix}{σ}_{z , mag}^{2} & 0 \\ 0 & {σ}_{z , foc}^{2}\end{matrix} ) . \qquad ( 55 )$$

Possibly the measurement noise could also be estimated from the individual multi-pixel image of the secondary beamlets in each timestep.

For the initial state one can for example assume

$${x}_{0 \vert 0} = ( \begin{matrix}0 \\ 0 \\ 0 \\ 0\end{matrix} )$$

$$and$$

$${P}_{0 \vert 0} = ( \begin{matrix}{σ}_{0 , mag}^{2} & 0 & \frac{{σ}_{0 , mag}^{2}}{{c}_{mag / foc}} & 0 \\ 0 & {σ}_{0 , \dot{mag}}^{2} & 0 & \frac{{σ}_{0 , \dot{mag}}^{2}}{{c}_{mag / foc}} \\ \frac{{σ}_{0 , mag}^{2}}{{c}_{mag / foc}} & 0 & \frac{{σ}_{0 , mag}^{2}}{{c}_{mag / foc}^{2}} & 0 \\ 0 & \frac{{σ}_{0 , \dot{mag}}^{2}}{{c}_{mag / foc}} & 0 & \frac{{σ}_{0 , \dot{mag}}^{2}}{{c}_{mag / foc}^{2}}\end{matrix} )$$

This shape of the covariance matrix P_{0|0} incorporates the assumption that the amount of defocus is related to the change of inter-beam pitch (magnification change) via a conversion factor c_{mag/foc}: The off-diagonal entries specify a correlation between m\dot{a}g and f\dot{o}c and m\dot{a}g and f\dot{o}c.

With this information and the formulas of the prediction step and the update step indicated above, one can compute x_{k|k} at each measurement time giving an estimation of the system state (pitch change, defocus and their time derivatives). To correct these effects with the corrective elements one can now predict the system state at a later time (for example the mean time between the next two adjustment times): This again can be described as the prediction step of a Kalman filter with

$${F}_{p} = ( \begin{matrix}1 & Δ {t}_{p} & 0 & 0 \\ 0 & 1 & 0 & 0 \\ 0 & 0 & 1 & Δ {t}_{p} \\ 0 & 0 & 0 & 1\end{matrix} ) \qquad ( 56 )$$

with Δtₚ denoting the time between current timestep (the current measurement time) and the time one wants to predict to, and no control input, i.e.

$${x}_{p} = {F}_{p} {x}_{k \vert k} . \qquad ( 57 )$$

Accordingly, this corresponds to an extrapolation of the system state—including the defocus, rotation, translation, etc.—to a future timepoint.

The readjustment to the corrective elements is then given by

$$( \begin{matrix}Δ C 1 \\ Δ C 2\end{matrix} ) = {sens}^{- 1} \cdot ( \begin{matrix}{( {x}_{p} )}_{1} \\ {( {x}_{p} )}_{3}\end{matrix} ) \qquad ( 58 )$$

which is simultaneously the vector u used in the next timestep of the Kalman filter.

Generally, applying the filter is optional. It would also be possible to merely determine the control signals applied to the corrective elements based on the current transformation parameters, without refinement by the filter.

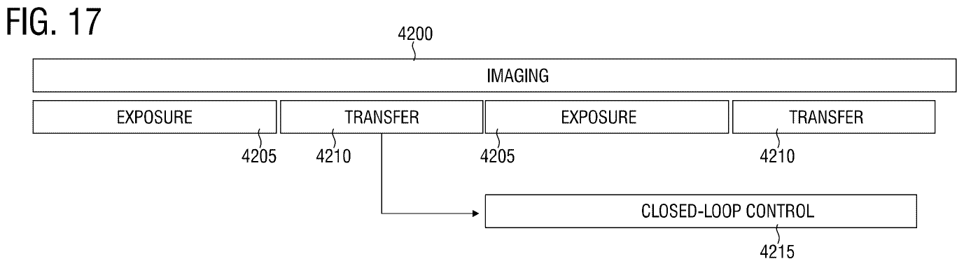

FIG. 17 schematically illustrates that the processing of the close-loop control process 1000 can be executed in parallel (box 4215) with the exposure of the multi-pixel detector and the image transfer (box 4205, 4210). This allows to reduce the refresh time between providing updated control signals, i.e., this allows to reduce the duration of a iteration 1021 of the close-loop control process.

Further, imaging is in parallel (at box 4200) with the control operations of boxes 4205, 4210, 4215. This is supported by using multiple detectors 232, 612 (cf. FIG. 5), one for imaging and one for acquiring measurements for the closed-loop control process 1000.

Summarizing, at least the following techniques have been disclosed.

EXAMPLE 1. A computer-implemented method of operating a multi-beam charged particle imaging device (1), the method comprising:
while raster-scanning a pattern (41.2) of multiple charged particle beams (3.1, 3.2, 3.3) across a sample object (7), implementing a closed-loop control process (1000),
wherein the closed-loop control process (1000) comprises stabilizing a pattern (41.3) of secondary beamlets (9.1, 9.2, 9.3, 9.4) towards a setpoint (41.3a, 1060),
wherein the closed-loop control process (1000) comprises capturing a multi-pixel image (1599) of the secondary beamlets (9.1, 9.2, 9.3, 9.4) and determining a current estimate (1055) of the pattern (41.3) of the secondary beamlets (9.1, 9.2, 9.3, 9.4) based on the multi-pixel image (1599) of the secondary beamlets (9.1, 9.2, 9.3, 9.4),
wherein a section (1025) of the closed-loop control process (1000) that determines the current estimate (1055) of the pattern (41.3) of the secondary beamlets (9.1, 9.2, 9.3, 9.4) based on the multi-pixel image (1599) is implemented at least partly in a field-controlled programmable array logic (1625).

EXAMPLE 2. The computer-implemented method of EXAMPLE 1,
wherein the closed-loop control process (1000) further comprises determining an affine transformation (1580) between the current estimate (1055) of the pattern (41.3) of the secondary beamlets (9.1, 9.2, 9.3, 9.4) and the setpoint (41.3a, 1060).

EXAMPLE 3. The computer-implemented method of EXAMPLE 2,
wherein a section (1015) of the closed-loop control process (1000) that determines the affine transformation (1580) is implemented at least partly in a microprocessor (1615).

EXAMPLE 4. The computer-implemented method of EXAMPLE 2 or 3,
wherein the affine transformation (1580) is determined by executing a least square fit of transformation parameters of the affine transformation.

EXAMPLE 5. The computer-implemented method of EXAMPLE 4,
wherein the least square fit is executed using a predetermined pseudoinverse of a transformation matrix determined based on the setpoint (41.3a, 1060).

EXAMPLE 6. The computer-implemented method of EXAMPLE 5, further comprising:
prior to implementing (3010) the closed-loop control process (1000), implementing (3005) a calibration process,
wherein the calibration process comprises capturing a further multi-pixel image of the secondary beamlets and determining the pseudoinverse of the transformation matrix based on the further multi-pixel image.

EXAMPLE 7. The computer-implemented method of any one of the preceding EXAMPLES,
wherein the closed-loop control process (1000) comprises applying at least one of a rotation, a translation, or a magnification to the secondary beamlets (9.1, 9.2, 9.3, 9.4) based on the current estimate (1055) of the pattern (41.3) of the secondary beamlets (9.1, 9.2, 9.3, 9.4) and by applying control signals to one or more corrective elements (201.1, 201.2, 201.3, 201.4, 201.5, 205.4, 205.5, 216, 222) arranged in a beam path of the secondary beamlets (9.1, 9.2, 9.3, 9.4).

EXAMPLE 8. The computer-implemented method of any one of EXAMPLEs 2 to 6, and of EXAMPLE 7,
wherein the at least one of the rotation, the translation, or the magnification is determined based on transformation parameters of the affine transformation (1580).

EXAMPLE 9. The computer-implemented method of EXAMPLE ,
wherein the at least one of the rotation, the translation, or the magnification is determined using a filter (4005) operating based on an evolution of the transformation parameters across multiple iterations (1021) of the closed-loop control process (1000) and a state transition model for a change of the transformation parameters from iteration to iteration (1021).

EXAMPLE 10. The computer-implemented method of EXAMPLE 9,
wherein the filter is a Kalman filter.

EXAMPLE 11. The computer-implemented method of any one of EXAMPLE 7 to 10,
wherein the at least one of the rotation or the translation is determined by extrapolating the current estimate (1055) of the pattern (41.3) of the secondary beamlets (9.1, 9.2, 9.3, 9.4) to a future point in time based on an evolution of the current estimate (1055) of the secondary beamlets (9.1, 9.2, 9.3, 9.4) across multiple iterations (1021) of the closed-loop control process (1000).

EXAMPLE 12. The computer-implemented method of any one of the preceding EXAMPLES,
wherein the closed-loop control process (1000) further comprises minimizing a defocus of the secondary beamlets (9.1, 9.2, 9.3, 9.4) based on a size of the secondary beamlets (9.1, 9.2, 9.3, 9.4) in the multi-pixel image (1599).

EXAMPLE 13. The computer-implemented method of EXAMPLE 12,
wherein a direction of the defocus is determined based on an inter-beamlet pitch of the current estimate (1055) of the pattern (41.3) of the secondary beamlets (9.1, 9.2, 9.3, 9.4).

EXAMPLE 14. The computer-implemented method of EXAMPLE 13, further comprising:
prior to implementing (3010) the closed-loop control process (1000), implementing (3005) a calibration process,
wherein the calibration process comprises capturing further multi-pixel images of the secondary beamlets (9.1, 9.2, 9.3, 9.4) at multiple charging levels of the sample and determining a look-up table linking inter-beamlet pitch to defocus based on the further multi-pixel images.

EXAMPLE 15. The computer-implemented method of any one of the preceding EXAMPLES,
wherein the determining of the current estimate (1055) of the pattern (41.3) of the secondary beamlets (9.1, 9.2, 9.3, 9.4) comprises determining a difference image (1598) between the multi-pixel image (1599) of the secondary beamlets (9.1, 9.2, 9.3, 9.4) and a multi-pixel reference image (1597) associated with the setpoint (41.3a, 1060).

EXAMPLE 16. The computer-implemented method of any one of EXAMPLEs 1 to 14,
wherein the determining of the current estimate (1055) of the pattern (41.3) of the secondary beamlets (9.1, 9.2, 9.3, 9.4) comprises determining (3110) positions of centers (15.1, 15.2, 15.3, 15.4) for each secondary beamlet (9.1, 9.2, 9.3, 9.4).

EXAMPLE 17. The computer-implemented method of EXAMPLE 16,
wherein the determining of the positions of the centers (15.1, 15.2, 15.3, 15.4) of each secondary beamlet (9.1, 9.2, 9.3, 9.4) comprises determining a local maximum of a pixel intensity (1570) for each one of a plurality of predetermined pixel clusters (1520.1, 1520.2, 1520.3, 1520.4) of multiple pixels (1505) of the multi-pixel image (1599).

EXAMPLE 18. The computer-implemented method of EXAMPLE 17,
wherein the determining of the positions of the centers (15.1, 15.2, 15.3, 15.4) of each secondary beamlet (9.1, 9.2, 9.3, 9.4) comprises performing a matrix multiplication of a sparse matrix selecting the pixel clusters (1520.1, 1520.2, 1520.3, 1520.4) and a measurement vector indicative of the intensities (1570) of each pixel (1505) of the multi-pixel image (1599).

EXAMPLE 19. The computer-implemented method of EXAMPLE 15,
wherein the sparse matrix is pre-coded in the field-programmable array logic.

EXAMPLE 20. A computer-implemented method of operating a multi-beam charged particle imaging device (1), the method comprising:
determining one or more closed-loop control parameters in a calibration process (3005),
loading a sample object (7) into the multi-beam charged particle imaging device, and
imaging the sample object using the multi-beam charged particle imaging device (1) and contemporaneously applying a closed-loop control of at least one parameter of secondary beamlets (9.1, 9.2, 9.3, 9.4), the closed-loop control being based on the one or more closed-loop control parameters.

EXAMPLE 21. The computer-implemented method of EXAMPLE 20,
wherein the at least one parameter of the secondary beamlets comprises a pattern of the secondary beamlets in an imaging plane (225) of the multi-beam charged particle imaging device (1).

EXAMPLE 22. The computer-implemented method of EXAMPLE 21,
wherein the one or more closed-loop control parameters comprise a least-square fit matrix for fitting a current estimate of a pattern of secondary beamlets to a reference pattern determined in the calibration procedure.

EXAMPLE 23. The computer-implemented method of any one of EXAMPLEs 20 to 22, further comprising:
applying at least one of the one or more closed-loop control parameters using a field-programmable array logic.

EXAMPLE 24. The computer-implemented method of any one of EXAMPLEs 20 to 23,
wherein the one or more closed-loop control parameters comprise a sparse matrix for multiplication with a measurement vector indicative of pixel intensities of a pixel intensity of a multi-pixel image of the secondary beamlets.

EXAMPLE 25. The computer-implemented method of any one of EXAMPLEs 20 to 24,
wherein the one or more imaging parameters comprise a defocus of the secondary beamlets with respect to an imaging plane of a detector system of the multi-beam charged particle imaging device.

EXAMPLE 26. A computer-implemented method of operating a multi-beam charged particle imaging device, the method comprising:
while raster-scanning a pattern of multiple charged particle beams across a sample, implementing a closed-loop control process,
wherein the closed-loop control process comprises stabilizing one or more parameters of the secondary beamlets towards a setpoint based on a multi-pixel image of the secondary beamlets.

EXAMPLE 27. The computer-implemented method of EXAMPLE 26,
wherein the one or more imaging parameters comprise a pattern of the secondary beamlets in an imaging plane of a detector system of the multi-beam charged particle imaging device.

EXAMPLE 28. The computer-implemented method of EXAMPLE 26 or 27,
wherein the one or more imaging parameters comprise a defocus of the secondary beamlets with respect to an imaging plane of a detector system of the multi-beam charged particle imaging device.

EXAMPLE 29. The computer-implemented method of any one of EXAMPLEs 26 to 28, further comprising:
determining a magnification of the pattern based on the multi-pixel image,
determining a width of the secondary beamlets based on the multi-pixel image, and
determining a current estimate of the defocus based on the magnification and the width of the secondary beamlets.

EXAMPLE 30. A control circuitry for operating a multi-beam charged particle imaging device, configured to execute the method of any one of EXAMPLES 1 to 29.

EXAMPLE 31. A computer program comprising program code executable by a control logic, executing of the program code causing the control logic to execute the method of any one of EXAMPLES 1 to 29.

Although the disclosure has been shown and described with respect to certain embodiments, equivalents and modifications will occur to others skilled in the art upon the reading and understanding of the specification. The present disclosure includes all such equivalents and modifications and is limited only by the scope of the appended claims.

What is claimed is:

1. A computer-implemented method of operating a multi-beam charged particle imaging device, the computer-implemented method comprising:
implementing a closed-loop control process while raster-scanning a pattern of multiple charged particle beams generated by the multi-beam charged particle imaging device across an object,
wherein:
a pattern of secondary beamlets is generated via an interaction of the multiple charged particle beams with the object;
the closed-loop control process comprises stabilizing the pattern of secondary beamlets generated toward a setpoint;
the closed-loop control process comprises capturing a multi-pixel image of the secondary beamlets and determining a current estimate of the pattern of the secondary beamlets based on the multi-pixel image of the secondary beamlets;
a section of the closed-loop control process that determines the current estimate of the pattern of the secondary beamlets based on the multi-pixel image is at least partly implemented in a field-controlled programmable array logic; and
determining the current estimate of the pattern of the secondary beamlets and stabilizing the pattern of secondary beamlets is performed using matrix multiplication operations.

2. The computer-implemented method of claim 1, wherein the closed-loop control process further comprises determining an affine transformation between the current estimate of the pattern of the secondary beamlets and the setpoint.

3. The computer-implemented method of claim 2, wherein a section of the closed-loop control process that determines the affine transformation is at least partly implemented in a microprocessor.

4. The computer-implemented method of claim 2, wherein the affine transformation is determined by executing a least square fit of transformation parameters of the affine transformation.

5. The computer-implemented method of claim 4, wherein the least square fit is executed using a predetermined pseudoinverse of a transformation matrix determined based on the setpoint.

6. The computer-implemented method of claim 5, further comprising, prior to implementing the closed-loop control process, implementing a calibration process which comprises capturing a further multi-pixel image of the secondary beamlets and determining the pseudoinverse of the transformation matrix based on the further multi-pixel image.

7. The computer-implemented method of claim 1, wherein the closed-loop control process comprises:
applying at least one of a rotation, a translation, or a magnification to the secondary beamlets based on the current estimate of the pattern of the secondary beamlets; and
applying control signals to one or more corrective elements arranged in a beam path of the secondary beamlets.

8. The computer-implemented method of claim 7, wherein:
the closed-loop control process further comprises determining an affine transformation between the current estimate of the pattern of the secondary beamlets and the setpoint; and
the at least one of the rotation, the translation, or the magnification is determined based on transformation parameters of the affine transformation.

9. The computer-implemented method of claim 8, wherein the at least one of the rotation, the translation, or the magnification is determined using a filter operating based on an evolution of the transformation parameters across multiple iterations of the closed-loop control process and a state transition model for a change of the transformation parameters from iteration to iteration.

10. The computer-implemented method of claim 9, wherein the filter comprises a Kalman filter.

11. The computer-implemented method of claim 7, wherein:
the at least one of the rotation, the translation, or the magnification comprises the at least one of the rotation and the translation; and
the at least one of the rotation or the translation is determined by extrapolating the current estimate of the pattern of the secondary beamlets to a future point in time based on an evolution of the current estimate of the secondary beamlets across multiple iterations of the closed-loop control process.

12. The computer-implemented method of claim 1, wherein the closed-loop control process further comprises minimizing a defocus of the secondary beamlets based on a size of the secondary beamlets in the multi-pixel image.

13. The computer-implemented method of claim 12, wherein a direction of the defocus is determined based on an inter-beamlet pitch of the current estimate of the pattern of the secondary beamlets.

14. The computer-implemented method of claim 13, further comprising, prior to implementing the closed-loop control process, implementing a calibration process which comprises:
capturing further multi-pixel images of the secondary beamlets at multiple charging levels of the object; and
determining a look-up table linking inter-beamlet pitch to defocus based on the further multi-pixel images.

15. The computer-implemented method of claim 1, wherein determining the current estimate of the pattern of the secondary beamlets comprises determining a difference image between the multi-pixel image of the secondary beamlets and a multi-pixel reference image associated with the setpoint.

16. The computer-implemented method of claim 1, wherein determining the current estimate of the pattern of the secondary beamlets comprises determining a position of a center for each secondary beamlet.

17. The computer-implemented method of claim 16, wherein determining the position of the center of each secondary beamlet comprises determining a local maximum of a pixel intensity for each one of a plurality of predetermined pixel clusters of multiple pixels of the multi-pixel image.

18. The computer-implemented method of claim 17, wherein determining the position of the center of each secondary beamlet comprises performing a matrix multiplication of a sparse matrix selecting the pixel clusters and a measurement vector indicative of the intensities of each pixel of the multi-pixel image.

19. The computer-implemented method of claim 18, wherein the sparse matrix is pre-coded in the field-programmable array logic.

20. One or more machine-readable hardware storage device comprises instructions that are executable by one or more processing devices to perform operations comprising the method of claim 1.

21. A system, comprising:
one or more processing devices; and
one or more machine-readable hardware storage device comprises instructions that are executable by the one or more processing devices to perform operations comprising the method of claim 1.

22. A computer-implemented method of operating a multi-beam charged particle imaging device, the computer-implemented method comprising:
raster-scanning a pattern of multiple charged particle beams generated by the multi-beam charged particle imaging device across an object, thereby generating a pattern of secondary beamlets due to an interaction of the multiple charged particle beams with the object; and
while raster-scanning, implementing a closed-loop control process which comprises:
stabilizing the pattern of secondary beamlets generated toward a setpoint; and
using matrix multiplication operations to capture a multi-pixel image of the secondary beamlets and to determine a current estimate of the pattern of the secondary beamlets based on the multi-pixel image of the secondary beamlets,
wherein a section of the closed-loop control process that determines the current estimate of the pattern of the secondary beamlets based on the multi-pixel image is at least partly implemented in a field-controlled programmable array logic.
